(19) United States
(12) Patent Application Publication
(10) Pub. No.: US 2024/0264532 A1
(43) Pub. Date: Aug. 8, 2024

(54) TREATMENT LIQUID AND TREATMENT LIQUID HOUSING BODY

(71) Applicant: FUJIFILM Corporation, Tokyo (JP)

(72) Inventors: Tetsuya SHIMIZU, Haibara-gun (JP); Michihiro Shirakawa, Haibara-gun (JP); Satomi Takahashi, Haibara-gun (JP)

(73) Assignee: FUJIFILM Corporation, Tokyo (JP)

(21) Appl. No.: 18/603,841

(22) Filed: Mar. 13, 2024

Related U.S. Application Data
(63) Continuation of application No. PCT/JP2022/031471, filed on Aug. 22, 2022.

(30) Foreign Application Priority Data
Sep. 17, 2021 (JP) 2021-152400
Jan. 28, 2022 (JP) 2022-011363

(51) Int. Cl. G03F 7/32; G03F 7/20

(52) U.S. Cl. CPC G03F 7/325; G03F 7/2004

(57) ABSTRACT

An object of the present invention is to provide a treatment liquid that, when used as a developer or a rinsing liquid, is less likely to cause defects when applied onto a surface to be coated and, in addition, is less likely to cause defects on a surface to be coated also when used after being housed in a container whose inner wall surface is made of metal. Another object of the present invention is to provide a treatment liquid housing body. A treatment liquid according to the present invention is a treatment liquid including an aliphatic hydrocarbon solvent, an acid component that is at least one selected from the group consisting of carboxylic acids having a hydrocarbon group having 1 to 3 carbon atoms and formic acid, and a metallic impurity including a metallic element that is at least one selected from the group consisting of Fe, Ni, and Cr. The mass ratio of the content of the metallic element to the content of the acid component is 1.0×10⁻⁹ to 3.0×10⁻⁵.

### CROSS-REFERENCE TO RELATED APPLICATIONS

This application is a Continuation of PCT International Application No. PCT/JP2022/031471 filed on Aug. 22, 2022, which claims priority under 35 U.S.C. § 119(a) to Japanese Patent Application No. 2021-152400 filed on Sep. 17, 2021 and Japanese Patent Application No. 2022-011363 filed on Jan. 28, 2022. The above applications are hereby expressly incorporated by reference, in their entirety, into the present application.

### BACKGROUND OF THE INVENTION

### 1. Field of the Invention

The present invention relates to a treatment liquid and a treatment liquid housing body.

### 2. Description of the Related Art

In a process for producing a semiconductor device such as an integrated circuit (IC) or a large scale integrated circuit (LSI), micromachining by a photolithography process using a photoresist composition has been conventionally performed.

In such a photolithography process, after a coating film is formed using a photoresist composition (an actinic ray-sensitive or radiation-sensitive resin composition, also referred to as a chemical amplification resist composition), the coating film obtained is exposed and then developed with a developer to obtain a pattern-shaped cured film, and, furthermore, the cured film after the development is washed with a rinsing liquid.

For example, WO2020/071261A discloses that a chemical liquid which contains an organic solvent, an organic impurity including a phosphate and an adipate, and a metallic impurity and in which the mass ratio of the content of the phosphate to the content of the adipate is equal to or more than a predetermined value is used as a developer and a rinsing liquid.

### SUMMARY OF THE INVENTION

In WO2020/071261A, a phosphate and an adipate are included as essential components, but the present inventors have found that without using these components, when a treatment liquid including an aliphatic hydrocarbon solvent as an organic solvent and a metallic component is used as a rinsing liquid or a developer, a defect may occur on a surface to be coated, leaving room for improvement. Such a defect is probably due to impurities generated in the treatment liquid during at least one of production or storage.

Thus, an object of the present invention is to provide a treatment liquid that, when used as a developer or a rinsing liquid, is less likely to cause defects when applied onto a surface to be coated and, in addition, is less likely to cause defects on a surface to be coated also when used after being housed in a container whose inner wall surface is made of metal. Another object of the present invention is to provide a treatment liquid housing body.

To achieve the above objects, the present inventors have conducted intensive studies and found that the above objects can be achieved by the following configurations.
[1] A treatment liquid including:
an aliphatic hydrocarbon solvent;
an acid component that is at least one selected from the group consisting of carboxylic acids having a hydrocarbon group having 1 to 3 carbon atoms and formic acid; and
a metallic impurity including a metallic element that is at least one selected from the group consisting of Fe, Ni, and Cr,
wherein a mass ratio of a content of the metallic element to a content of the acid component is 1.0×10⁻⁹ to 3.0×10⁻⁵.
[2] The treatment liquid according to [1], wherein the content of the metallic element is 0.03 to 100 mass ppt relative to a total mass of the treatment liquid.
[3] The treatment liquid according to [1] or [2], wherein the content of the acid component is 1 to 2000 mass ppm relative to a total mass of the treatment liquid.
[4] The treatment liquid according to any one of [1] to [3], wherein the acid component includes acetic acid, and
a content of the acetic acid is 5 to 50 mass ppm relative to a total mass of the treatment liquid.
[5] The treatment liquid according to any one of [1] to [4], wherein a content of the aliphatic hydrocarbon solvent is 2 to 70 mass % relative to a total mass of the treatment liquid.
[6] The treatment liquid according to any one of [1] to [5], wherein the aliphatic hydrocarbon solvent includes least one selected from the group consisting of nonane, decane, undecane, dodecane, and methyldecane.
[7] The treatment liquid according to any one of [1] to [6], further including an aromatic hydrocarbon.
[8] The treatment liquid according to [7], wherein a mass ratio of the content of the acid component to a content of the aromatic hydrocarbon is 1.0×10⁻³ to 5.
[9] The treatment liquid according to [7] or [8], wherein a content of the aromatic hydrocarbon is 1 to 2000 mass ppm relative to a total mass of the treatment liquid.
[10] The treatment liquid according to any one of [1] to [9], further including an ester solvent.
[11] The treatment liquid according to [10], wherein a content of the ester solvent is 30 to 99 mass % relative to a total mass of the treatment liquid.
[12] The treatment liquid according to or [11], wherein the ester solvent includes butyl acetate.
[13] The treatment liquid according to any one of [1] to [12], further including water,
wherein a content of the water is 1 to 1000 mass ppm relative to a total mass of the treatment liquid.
[14] The treatment liquid according to any one of [1] to [13], further including a sulfur-containing compound,
wherein a content of the sulfur-containing compound is 0.01 to 10 mass ppm relative to a total mass of the treatment liquid.
[15] The treatment liquid according to any one of [1] to [14], further including an alcohol,
wherein a content of the alcohol is 1 to 5000 mass ppm relative to a total mass of the treatment liquid.
[16] The treatment liquid according to any one of [1] to [15], wherein the treatment liquid is used as a developer or a rinsing liquid.
[17] The treatment liquid according to any one of [1] to [16], wherein the treatment liquid is used as a developer for a negative-type resist film exposed with extreme ultraviolet rays.
[18] A treatment liquid housing body including:
a container; and
the treatment liquid according to any one of [1] to housed in the container.
[19] The treatment liquid housing body according to [18], wherein at least a part of a liquid-contact portion of the container is made of metal.

The present invention can provide a treatment liquid that, when used as a developer or a rinsing liquid, is less likely to cause defects when applied onto a surface to be coated and, in addition, is less likely to cause defects on a surface to be coated also when used after being housed in a container whose inner wall surface is made of metal. The present invention can also provide a treatment liquid housing body.

### DESCRIPTION OF THE PREFERRED EMBODIMENTS

Hereinafter, the present invention will be described in detail.

It should be appreciated that although the description of constituent features given below may be made on the basis of representative embodiments of the present invention, the present invention is not limited to these embodiments.

In the present specification, any numerical range expressed using “to” means a range including numerical values before and after “to” as lower and upper limit values. In numerical ranges described in stages in the present specification, the upper limit value or the lower limit value described in one numerical range may be replaced with the upper limit value or the lower limit value of other numerical ranges described in stages. In numerical ranges described in the present specification, the upper limit value or the lower limit value described in one numerical range may be replaced with values described in Examples.

In the present specification, if there are two or more substances corresponding to one component in a treatment liquid, the amount of the component in the treatment liquid means the total amount of the two or more substances present in the treatment liquid unless otherwise specified.

In the present invention, “ppm” means “parts-per-million (10⁻⁶)”, “ppb” means “parts-per-billion (10⁻⁹)”, “ppt” means “parts-per-trillion (10⁻¹²)”, and “ppq” means “parts-per-quadrillion (10⁻¹⁵)”.

In the present invention, 1 Å (Angstrom) corresponds to 0.1 nm.

Regarding expressions of groups (atomic groups) in the present invention, an expression not specified as substituted or unsubstituted encompasses a group having no substituents and also a group having a substituent to the extent that the advantageous effects of the present invention are not impaired. For example, a “hydrocarbon group” encompasses not only a hydrocarbon group having no substituents (an unsubstituted hydrocarbon group) but also a hydrocarbon group having a substituent (a substituted hydrocarbon group). This applies to every compound.

The term “radiation” in the present invention means, for example, far ultraviolet rays, extreme ultraviolet rays (EUV), X-rays, or an electron beam. In the present invention, light means an actinic ray or a radiation. The term “exposure” in the present invention includes, unless otherwise specified, not only exposure with, for example, far ultraviolet rays, X-rays, or EUV but also patterning with a corpuscular beam such as an electron beam or an ion beam.

In the present specification, a combination of two or more preferred embodiments is a more preferred embodiment.

### Treatment Liquid

A treatment liquid according to the present invention (hereinafter also referred to as “the present treatment liquid”) is a treatment liquid including an aliphatic hydrocarbon solvent, an acid component (hereinafter also referred to as a “specific acid component”) that is at least one selected from the group consisting of carboxylic acids having a hydrocarbon group having 1 to 3 carbon atoms and formic acid, and a metallic impurity (hereinafter also referred to as a “specific metallic impurity”) including a metallic element (hereinafter also referred to as a “specific metallic element”) that is at least one selected from the group consisting of Fe, Ni, and Cr. The mass ratio of the content of the metallic element to the content of the acid component is 1.0×10⁻⁹ to 3.0×10⁻⁵.

The present treatment liquid, when used as a developer or a rinsing liquid, is less likely to cause defects when applied onto a surface to be coated and, in addition, is less likely to cause defects on a surface to be coated also when used after being housed in a container whose inner wall surface is made of metal.

While the reason for this has yet to be fully elucidated, it is presumed that since the content of the specific metallic element relative to the content of the specific acid component is within the predetermined range in the system including the aliphatic hydrocarbon solvent, the specific acid component and the specific metallic component interact well with each other, thus inhibiting impurities that can cause defects from occurring in the treatment liquid.

When a treatment liquid including an acid component is housed in a container whose inner wall surface is made of metal, the acid component may react with the metal forming the inner wall surface of the container to cause impurities. For this problem, it is presumed that since the content of the specific metallic element relative to the content of the specific acid component is within the predetermined range in the system including the aliphatic hydrocarbon solvent, the specific acid component and the specific metallic component interact well with each other in the treatment liquid, thus inhibiting the reaction between the acid component in the treatment liquid and the metal forming the inner wall surface.

### Aliphatic Hydrocarbon Solvent

The present treatment liquid includes an aliphatic hydrocarbon solvent. The aliphatic hydrocarbon solvent is a component included in the present treatment liquid as an organic solvent.

In the present specification, the organic solvent is an organic solvent contained in an amount of 8000 mass ppm or more relative to the total mass of the present treatment liquid. Organic solvents contained in an amount of less than 8000 mass ppm relative to the total mass of the present treatment liquid fall under the category of organic impurities and are not regarded as the organic solvent.

The aliphatic hydrocarbon solvent may be linear, branched, or cyclic (monocyclic or polycyclic), and is preferably linear. The aliphatic hydrocarbon solvent may be a saturated aliphatic hydrocarbon or an unsaturated aliphatic hydrocarbon.

The number of carbon atoms of the aliphatic hydrocarbon solvent is often 2 or more, preferably 5 or more, more preferably 9 or more. The upper limit is preferably 30 or less, more preferably 20 or less, still more preferably 15 or less, particularly preferably 13 or less. Specifically, the number of carbon atoms of the aliphatic hydrocarbon solvent is preferably 11.

Examples of the aliphatic hydrocarbon solvent include pentane, isopentane, hexane, isohexane, cyclohexane, ethylcyclohexane, methylcyclohexane, heptane, octane, isooctane, nonane, decane, methyldecane, undecane, dodecane, tridecane, tetradecane, pentadecane, hexadecane, hepradecane, 2,2,4-trimethylpentane, and 2,2,3-trimethylhexane.

For higher functions as a developer and a rinsing liquid, the aliphatic hydrocarbon solvent preferably includes an aliphatic hydrocarbon having 5 or more carbon atoms (preferably 20 or less carbon atoms), more preferably includes an aliphatic hydrocarbon having 9 or more carbon atoms (preferably 13 or less carbon atoms), still more preferably includes at least one selected from the group consisting of nonane, decane, undecane, dodecane, and methyldecane, particularly preferably includes undecane.

One aliphatic hydrocarbon solvent may be used alone, or two or more aliphatic hydrocarbon solvents may be used in combination.

For higher functions as a developer and a rinsing liquid, the content of the aliphatic hydrocarbon solvent is preferably 1 mass % or more and less than 100 mass %, more preferably 2 to 70 mass %, still more preferably 5 to 30 mass %, relative to the total mass of the present treatment liquid.

When the content of the aliphatic hydrocarbon solvent is 2 mass % or more, a resist pattern with higher resolution is provided.

When the content of the aliphatic hydrocarbon solvent is 70 mass % or less, the occurrence of, for example, resist pattern collapse can be further suppressed, and when the content of the aliphatic hydrocarbon solvent is 30 mass % or less, the generation of, for example, static electricity can be further suppressed.

### Specific Acid Component

The present treatment liquid includes a specific acid component. The specific acid component means carboxylic acids having a hydrocarbon group having 1 to 3 carbon atoms and formic acid, as described above. The specific acid component may be ionized to be present in the form of ions in the present treatment liquid.

The specific acid component may be included in a raw material (e.g., an organic solvent) used to produce the present treatment liquid, may be intentionally added during the process of producing the present treatment liquid, or may be transferred from, for example, an apparatus for producing the present treatment liquid during the process of producing the present treatment liquid (what is called contamination).

Specific examples of carboxylic acids having a hydrocarbon group having 1 to 3 carbon atoms include fatty acids having an alkyl group having 1 to 3 carbon atoms, such as acetic acid, propionic acid, n-butanoic acid (butyric acid), and 2-methylpropane acid (isobutyric acid), and polycarboxylic acids having a hydrocarbon group having 1 to 3 carbon atoms, such as malonic acid, succinic acid, glutaric acid, maleic acid, and fumaric acid. For the advantageous effects of the present invention to be better produced, fatty acids having an alkyl group having 1 to 3 carbon atoms are preferred.

The content of the specific acid component is preferably 1 to 2000 mass ppm, more preferably 3 to 700 mass ppm, still more preferably 5 to 50 mass ppm, relative to the total mass of the present treatment liquid. When the content of the specific acid component is in the above range, the advantageous effects of the present invention are better produced.

One specific acid component may be used alone, or two or more specific acid components may be used in combination.

Examples of methods for adjusting the content of the specific acid component include selecting raw materials with low specific acid component contents as raw materials constituting various components, performing distillation under conditions where contamination is suppressed by, for example, lining the inside of an apparatus with Teflon (registered trademark), and adding the specific acid component.

In one preferred embodiment of the present treatment liquid, for example, the specific acid component includes acetic acid, and the content of the acetic acid is 5 to 50 mass ppm relative to the total mass of the present treatment liquid. The present treatment liquid in such an embodiment produces the advantageous effects of the present invention in a better manner and is more suitable for use as a rinsing liquid and a developer.

### Specific Metallic Impurity

The present treatment liquid includes a specific metallic impurity including a specific metallic element. The specific metallic element means Fe, Ni, and Cr as described above, and the specific metallic impurity includes at least one metallic element selected from these metallic elements.

While the reason for this is not fully understood, the specific metallic element, compared with other metallic elements, is particularly closely related to the defect suppression performance of the treatment liquid. Thus, for example, controlling the content of the specific metallic element helps provide higher defect suppression performance.

The specific metallic impurity may be included in the present treatment liquid in the form of particles (metal-containing particles), may be included in the present treatment liquid in the form of ions (metal ions), or may be included in the present treatment liquid in both of these forms.

The specific metallic impurity may be included in a raw material (e.g., an organic solvent) used to produce the present treatment liquid, may be intentionally added during the process of producing the present treatment liquid, or may be transferred from, for example, an apparatus for producing the present treatment liquid during the process of producing the present treatment liquid (what is called contamination).

The content of the specific metallic element is preferably 0.03 to 100 mass ppt, more preferably 3 to 60 mass ppt, still more preferably 3 to 25 mass ppt, relative to the total mass of the present treatment liquid. When the content of the specific metallic element is in the above range, the advantageous effects of the present invention are better produced.

One specific metallic element may be used alone, or two or more specific metallic elements may be used in combination. When two or more specific metallic elements are included, their total content is in the above range.

The content of the specific metallic element is measured by inductively coupled plasma mass spectrometry (ICP-MS). In ICP-MS, the content of a metallic element to be measured is measured regardless of the form in which it is present.

For example, when the specific metallic impurity is included in the present treatment liquid in the form of metal-containing particles, the content of the specific metallic element in the metal-containing particles is measured. When the specific metallic impurity is included in the present treatment liquid in the form of metal ions, the content of the specific metallic element corresponding to the metal ions is measured. When the specific metallic impurity is included in the present treatment liquid in the forms of both metal-containing particles and metal ions, the sum of the content of the specific metallic element in the metal-containing particles and the content of the specific metallic element corresponding to the metal ions is measured.

The apparatus for ICP-MS is, for example, Agilent 8900 Triple Quadrupole ICP-MS (inductively coupled plasma mass spectrometry, for semiconductor analysis, option #200) manufactured by Agilent Technologies, Inc., and the measurement can be performed by a method described in EXAMPLES. As an alternative to this apparatus, NexION350S manufactured by PerkinElmer, Inc. or Agilent 8800 manufactured by Agilent Technologies, Inc. can also be used.

The mass ratio of the content of the specific metallic element to the content of the acid component (specific metallic element content/acid component content) is 1.0×10⁻⁹ to 3.0×10⁻⁵. To better produce the advantageous effects of the present invention, the mass ratio is preferably 6.0×10⁻⁹ to 2.5×10⁻⁵, more preferably 5.0×10⁻⁸ to 2.5×10⁻⁵, still more preferably 7.5×10⁻⁸ to 1.0×10⁻⁶.

Examples of methods for adjusting the content of the specific metallic element include selecting raw materials with low specific metallic element contents as raw materials constituting various components, performing distillation under conditions where contamination is suppressed by, for example, lining the inside of an apparatus with Teflon (registered trademark), and adding the specific metallic element or a compound including the specific metallic element.

### Ester Solvent

For higher functions as a developer and a rinsing liquid, the present treatment liquid preferably further includes an ester solvent, which is an organic solvent.

When the present treatment liquid includes an ester solvent together with the aliphatic hydrocarbon solvent, the advantageous effects of the present invention are better produced. While the reason for this has yet to be fully elucidated, it is presumed that since the content of the specific metallic element relative to the content of the specific acid component is within the predetermined range in the system including the ester solvent and the aliphatic hydrocarbon solvent, the specific acid component and the specific metallic component interact better with each other, thus suppressing the occurrence of impurities that can cause defects.

The ester solvent may be linear, branched, or cyclic (monocyclic or polycyclic), and is preferably linear.

The number of carbon atoms of the ester solvent is often 2 or more, preferably 3 or more, more preferably 4 or more, still more preferably 6 or more. The upper limit is often 20 or less, preferably 10 or less, more preferably 8 or less, particularly preferably 7 or less. Specifically, the number of carbon atoms of the ester solvent is preferably 6.

Specific examples of the ester solvent include butyl acetate, isobutyl acetate, tert-butyl acetate, methyl acetate, ethyl acetate, propyl acetate, isopropyl acetate, hexyl acetate, methoxybutyl acetate, amyl acetate, isoamyl acetate, methyl formate, ethyl formate, butyl formate, propyl formate, amyl formate, isoamyl formate, methyl lactate, ethyl lactate, butyl lactate, propyl lactate, methyl 2-hydroxyisobutyrate, ethyl butyrate, propyl butyrate, isopropyl butyrate, ethyl isobutyrate, propyl isobutyrate, ethyl propionate, propyl propionate, isopropyl propionate, butyl propionate, and isobutyl propionate.

The ester solvent preferably includes at least one selected from the group consisting of butyl acetate, isobutyl acetate, tert-butyl acetate, amyl acetate, isoamyl acetate, propyl propionate, isopropyl propionate, butyl propionate, isobutyl propionate, ethyl butyrate, propyl butyrate, isopropyl butyrate, ethyl isobutyrate, propyl isobutyrate, amyl formate, and isoamyl formate, more preferably includes butyl acetate.

One ester solvent may be used alone, or two or more ester solvents may be used in combination.

The content of the ester solvent is preferably 30 to 99 mass %, more preferably 30 to 98 mass %, still more preferably 70 to 95 mass %, relative to the total mass of the present treatment liquid.

### Water

The present treatment liquid may further include water. The water is not particularly limited, and may be, for example, distilled water, ion-exchanged water, or pure water.

The water may be added into the treatment liquid or may be unintentionally incorporated into the present treatment liquid during the process of producing the present treatment liquid. Examples of cases where the water is unintentionally incorporated during the process of producing the present treatment liquid include, but are not limited to, the case where the water is included in a raw material (e.g., an organic solvent) used to produce the present treatment liquid and the case where the water is incorporated during the process of producing the present treatment liquid (e.g., contamination).

The content of the water is preferably 1 to 1000 mass ppm, more preferably 5 to 100 mass ppm, relative to the total mass of the present treatment liquid. When the content of the water is in the above range, the advantageous effects of the present invention are better produced.

The content of the water in the present treatment liquid means a water content measured using an apparatus whose measurement principle is based on Karl Fischer water titration.

Examples of methods for adjusting the content of the water include selecting raw materials with low water contents as raw materials constituting various components, performing distillation under conditions where contamination is suppressed by, for example, lining the inside of an apparatus with Teflon (registered trademark), and adding water.

### Sulfur-Containing Compound

The present treatment liquid may further include a sulfur-containing compound. The sulfur-containing compound is not included in the category of organic solvents.

The sulfur-containing compound may be added into the treatment liquid or may be unintentionally incorporated into the present treatment liquid during the process of producing the present treatment liquid. Examples of cases where the sulfur-containing compound is unintentionally incorporated during the process of producing the present treatment liquid include, but are not limited to, the case where the sulfur-containing compound is included in a raw material (e.g., an organic solvent) used to produce the present treatment liquid and the case where the sulfur-containing compound is incorporated during the process of producing the present treatment liquid (e.g., contamination).

Examples of the sulfur-containing compound include thiol compounds, sulfide compounds, thiophene compounds, and hydrogen sulfide.

Examples of thiol compounds include methanethiol, ethanethiol, 3-methyl-2-butene-1-thiol, 2-methyl-3-furanthiol, furfurylthiol, 3-mercapto-3-methylbutyl formate, phenyl mercaptan, methylfurfuryl mercaptan, ethyl 3-mercaptobutanoate, 3-mercapto-3-methylbutanol, and 4-mercapto-4-methyl-2-pentanone.

Examples of sulfide compounds include dimethyl sulfide, dimethyl trisulfide, diisopropyl trisulfide, and bis(2-methyl-3-furyl) disulfide.

Examples of thiophene compounds include alkylthiophene compounds, benzothiophene compounds, dibenzothiophene compounds, phenanthrothiophene compounds, benzonaphthothiophene compounds, and thiophene sulfide compounds.

The sulfur-containing compound is preferably a sulfide compound or a thiophene compound, more preferably dimethyl sulfide or benzothiophene.

One sulfur-containing compound may be used alone, or two or more sulfur-containing compounds may be used in combination.

The content of the sulfur-containing compound is preferably 0.01 to 23 mass ppm, more preferably 0.01 to 10 mass ppm, still more preferably 0.01 to 9 mass ppm, particularly preferably 0.03 to 0.1 mass ppm, relative to the total mass of the present treatment liquid. When the content of the sulfur-containing compound is in the above range, the occurrence of defects can be further suppressed even when the present treatment liquid is used after being warmed.

The type and content of the sulfur-containing compound in the present treatment liquid can be determined using gas chromatography mass spectrometry (GCMS).

### Organic Impurities

The present treatment liquid may include organic impurities. The organic impurities may be added into the present treatment liquid or may be unintentionally incorporated during the process of producing the present treatment liquid. Examples of cases where the organic impurities are unintentionally incorporated during the process of producing the present treatment liquid include, but are not limited to, the case where the organic impurities are contained in a raw material (e.g., an organic solvent) used to produce the present treatment liquid and the case where the organic impurities are incorporated during the process of producing the present treatment liquid (e.g., contamination).

The content and type of the organic impurities in the present treatment liquid can be determined using gas chromatography mass spectrometry (GCMS).

### Aromatic Hydrocarbon

The present treatment liquid may further include an aromatic hydrocarbon, which is an organic impurity. The aromatic hydrocarbon is not included in the above-described organic solvent and falls under the category of organic impurities. In other words, the content of the aromatic hydrocarbon is less than 8000 mass ppm relative to the total mass of the present treatment liquid.

The number of carbon atoms of the aromatic hydrocarbon is preferably 6 to 30, more preferably 6 to 20, still more preferably 10 to 12.

The aromatic ring of the aromatic hydrocarbon may be a monocyclic ring or a polycyclic ring.

The number of ring members of the aromatic ring of the aromatic hydrocarbon is preferably 6 to 12, more preferably 6 to 8, still more preferably 6.

The aromatic ring of the aromatic hydrocarbon may further have a substituent. The substituent is, for example, an alkyl group, an alkenyl group, or a combination thereof. The alkyl group and the alkenyl group may be linear, branched, or cyclic. The number of carbon atoms of the alkyl group and the alkenyl group is preferably 1 to 10, more preferably 1 to 5.

The aromatic ring of the aromatic hydrocarbon is, for example, an optionally substituted benzene ring, an optionally substituted naphthalene ring, or an optionally substituted anthracene ring, preferably an optionally substituted benzene ring.

In other words, the aromatic hydrocarbon is preferably optionally substituted benzene.

The aromatic hydrocarbon preferably includes at least one selected from the group consisting of C₁₀H₁₄, C₁₁H₁₆, and C₁₀H₁₂.

The aromatic hydrocarbon is also preferably a compound represented by formula (c).

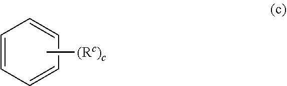

In formula (c), R^{c} represents a substituent, where c represents an integer of 0 to 6.

R^{c} represents a substituent.

The substituent represented by R^{c} is preferably an alkyl group or an alkenyl group.

The alkyl group and the alkenyl group may be linear, branched, or cyclic.

The number of carbon atoms of the alkyl group and the alkenyl group is preferably 1 to 10, more preferably 1 to 5.

When a plurality of R^{c}'s are present, the plurality of R^{c}'s may be the same or different, and the plurality of R^{c}'s may be bonded to each other to form a ring.

R^{c} (when a plurality of R^{c}'s are present, some or all of the plurality of R^{c}'s) and the benzene ring in formula (c) may be fused to form a fused ring.
c represents an integer of 0 to 6.
c is preferably an integer of 1 to 5, more preferably an integer of 1 to 4.

The molecular weight of the aromatic hydrocarbon is preferably 50 or more, more preferably 100 or more, still more preferably 120 or more. The upper limit is preferably 1000 or less, more preferably 300 or less, still more preferably 150 or less.

Examples of the aromatic hydrocarbon include C₁₀H₁₄ such as 1,2,4,5-tetramethyl-benzene, 1-ethyl-3,5-dimethyl-benzene, 1,2,3,5-tetramethyl-benzene, and 1-ethyl-2,4-dimethyl-benzene; C₁₁H₁₆ such as 1-methyl-4-(1-methylpropyl)-benzene and (1-methybutyl)-benzene; and C₁₀H₁₂ such as 1-methyl-2-(2-propenyl)-benzene and 1,2,3,4-tetrahydro-naphthalene.

The aromatic hydrocarbon is preferably 1,2,4,5-tetramethyl-benzene, 1-ethyl-3,5-dimethyl-benzene, 1,2,3,5-tetramethyl-benzene, 1-methyl-4-(1-methylpropyl)-benzene, or C₁₀H₁₂, more preferably 1-ethyl-3,5-dimethyl-benzene or 1,2,3,5-tetramethyl-benzene.

One aromatic hydrocarbon may be used alone, or two or more aromatic hydrocarbons may be used in combination.

The content of the aromatic hydrocarbon is preferably 1 to 3500 mass ppm, more preferably 1 to 2000 mass ppm, still more preferably 10 to 1200 mass ppm, particularly preferably 60 to 360 mass ppm, relative to the total mass of the present treatment liquid. When the content of the aromatic hydrocarbon is in the above range, the advantageous effects of the present invention are better produced.

The mass ratio of the content of the acid component to the content of the aromatic hydrocarbon (acid component content/aromatic hydrocarbon content) is preferably 1.0×10⁻³ to 5, more preferably 2.5×10⁻³ to 1.3, still more preferably 9.7×10⁻² to 8.3×10⁻¹. When the mass ratio is in the above range, the advantageous effects of the present invention are better produced.

Examples of methods for adjusting the content of the aromatic hydrocarbon include selecting raw materials with low aromatic hydrocarbon contents as raw materials constituting various components, performing distillation under conditions where contamination is suppressed by, for example, lining the inside of an apparatus with Teflon (registered trademark), and adding the aromatic hydrocarbon.

### Alcohol

The present treatment liquid may further include an alcohol, which is an organic impurity. The alcohol is not included in the above-described organic solvent and falls under the category of organic impurities. In other words, the content of the alcohol is less than 8000 mass ppm relative to the total mass of the treatment liquid.

The number of carbon atoms of the alcohol is preferably 1 to 20, more preferably 1 to 5, still more preferably 2 to 5.

The alcohol preferably includes at least one selected from the group consisting of ethanol, 1-propanol, 2-propanol, 1-butanol, 2-butanol, tert-butanol, 1-pentanol, 2-pentanol, 3-pentanol, and 2-methyl-1-butanol, more preferably includes 1-butanol, 2-butanol, or tert-butanol, still more preferably includes 1-butanol.

One alcohol may be used alone, or two or more alcohols may be used in combination.

The content of the alcohol is preferably 1 to 5000 mass ppm, more preferably 10 to 400 mass ppm, still more preferably 20 to 60 mass ppm, relative to the total mass of the present treatment liquid. When the content of the alcohol is in the above range, the advantageous effects of the present invention are better produced.

Examples of methods for adjusting the content of the alcohol include selecting raw materials with low alcohol contents as raw materials constituting various components, performing distillation under conditions where contamination is suppressed by, for example, lining the inside of an apparatus with Teflon (registered trademark), and adding the alcohol.

### Other Components

The present treatment liquid may include other components other than the foregoing.

Examples of the other components include organic solvents such as ketone solvents, amide solvents, and ether solvents and surfactants.

### Applications

For the advantageous effects of the present invention to be better produced, the present treatment liquid is suitably used as a developer or a rinsing liquid for use in the process of manufacturing a semiconductor device, more suitably used as a developer for a negative-type resist film exposed with extreme ultraviolet rays (EUV).

The present treatment liquid can also be used as a prewetting liquid for use in the process of manufacturing a semiconductor device.

The present treatment liquid is also suitable for treatment of a resist film exposed with a light source other than EUV. Specifically, the present treatment liquid is preferably used for treatment (particularly, development) of a resist composition (particularly, a negative-type resist film) to be exposed with KrF, ArF, ArF liquid immersion, or an electron beam (EB).

The present treatment liquid can also be used as a washing liquid for an end face and a peripheral inclined portion (bevel) of a wafer or a back-surface washing liquid (a washing liquid for a surface of a wafer on the side opposite to the side on which a semiconductor substrate is formed).

The present treatment liquid can also be used as a washing liquid for various manufacturing facilities, coating treatment apparatuses, and transfer containers.

### Method for Producing Treatment Liquid

The method for producing the present treatment liquid is not particularly limited, and a known production method can be used. In particular, to provide a treatment liquid that produces the advantageous effects of the present invention in a better manner, the method for producing the present treatment liquid preferably has a filtration step of filtering a purification target substance including an organic solvent using a filter to obtain the present treatment liquid.

The purification target substance used in the filtration step may be procured by purchase or the like or may be obtained by reacting raw materials together. The purification target substance preferably has a low impurity content. Examples of commercially available products of such a purification target substance include commercially available products called “high purity grade products”.

The method of obtaining a purification target substance (typically, a purification target substance containing an organic solvent) by reacting raw materials together is not particularly limited, and a known method can be used. For example, an organic solvent may be obtained by reacting one or more raw materials together in the presence of a catalyst.

### Filtration Step

A method for producing the present treatment liquid according to an embodiment of the present invention has a filtration step of filtering the purification target substance using a filter to obtain the present treatment liquid. The method of filtering the purification target substance using a filter is not particularly limited, but the purification target substance is preferably allowed to pass (flow) through a filter unit having a housing and a filter cartridge housed in the housing under pressure or non-pressure conditions.

### Pore Size of Filter

The pore size of the filter is not particularly limited, and a filter having a pore size commonly used for purification target substance filtration can be used. In particular, to more easily control the number of particles (e.g., metal-containing particles) that can be included in the present treatment liquid within a desired range, the pore size of the filter is preferably 200 nm or less, more preferably 20 nm or less, still more preferably 10 nm or less, particularly preferably 5 nm or less, most preferably 3 nm or less. The lower limit is not particularly limited, but in general, the lower limit is preferably 1 nm or more from the viewpoint of productivity.

In the present specification, the pore size and the pore size distribution of the filter mean a pore size and a pore size distribution determined using the bubble point of isopropanol (IPA) or HFE-7200 (“Novec 7200” manufactured by 3M, hydrofluoroether, C₄F₉OC₂H₅).

When the pore size of the filter is 5.0 nm or less, it is advantageous in that the number of particles contained in the present treatment liquid is more easily controlled. Hereinafter, a filter having a pore size of 5 nm or less is also referred to as a “micropore filter”.

The micropore filter may be used alone or in combination with a filter having a different pore size. In particular, combined use with a filter having a larger pore size is preferred from the viewpoint of higher productivity. If, in this case, the purification target substance preliminarily filtered through the filter having a larger pore size is allowed to flow through the micropore filter, clogging of the micropore filter can be prevented.

That is, when one filter is used, the pore size of the filter is preferably 5.0 nm or less, and when two or more filters are used, the pore size of a filter having a smallest pore size is preferably 5.0 nm or less.

The configuration in which two or more filters having different pore sizes are sequentially used is not particularly limited, but, for example, filter units as already described may be sequentially disposed along a conduit through which the purification target substance is transported. At this time, if the flow rate per unit time of the purification target substance is constant through the whole conduit, a filter unit having a smaller pore size may be subjected to a higher pressure than a filter unit having a larger pore size. In this case, it is preferable to make the pressure on the filter unit having a smaller pore size constant by disposing a pressure-regulating valve, a damper, and the like between the filter units or to increase the filtration area by disposing filter units housing the same filter in parallel along the conduit. This enables the number of particles in the present treatment liquid to be more stably controlled.

### Material of Filter

The material of the filter is not particularly limited and may be a known material. Specifically, in the case of a resin, examples include polyamides such as nylon (e.g., 6-nylon and 6,6-nylon); polyolefins such as polyethylene and polypropylene; polystyrene; polyimide; polyamide-imide; poly(meth)acrylate; polyfluorocarbons such as polytetrafluoroethylene, perfluoroalkoxyalkanes, perfluoroethylene propene copolymer, ethylene tetrafluoroethylene copolymer, ethylene-chlorotrifluoroethylene copolymer, polychlorotrifluoroethylene, polyvinylidene fluoride, and polyvinyl fluoride; polyvinyl alcohol; polyester; cellulose; and cellulose acetate. In particular, in terms of having higher solvent resistance and providing the present treatment liquid with higher defect suppression performance, at least one selected from the group consisting of nylon (particularly, 6,6-nylon is preferred), polyolefins (particularly, polyethylene is preferred), poly(meth)acrylate, and polyfluorocarbons (particularly, polytetrafluoroethylene (PTFE) and perfluoroalkoxyalkanes (PFA) are preferred) is preferred. These polymers can be used alone or in combination of two or more.

In addition to the resins, diatomaceous earth, glass, and the like may be used.

Alternatively, a polymer (e.g., nylon-grafted UPE) obtained by graft copolymerization of a polyolefin (e.g., UPE described later) with a polyamide (e.g., nylon such as nylon-6 or nylon-6,6) may be used as the material of the filter.

The filter may be a surface-treated filter. The method of the surface treatment is not particularly limited, and a known method can be used. Examples of the method of the surface treatment include chemical modification treatment, plasma treatment, hydrophilic/hydrophobic treatment, coating, gas treatment, and sintering.

The plasma treatment is preferred because the surface of the filter is hydrophilized. The water contact angle on the surface of the filtering material hydrophilized as a result of the plasma treatment is not particularly limited, but the static contact angle at 25° C. as measured with a contact angle meter is preferably 60° or less, more preferably 50° or less, particularly preferably 30° or less.

The chemical modification treatment is preferably introduction of an ion-exchange group into a base material.

That is, the filter is preferably a filter including any of the materials listed above as a base material and an ion-exchange group introduced into the base material. Typically, a filter including a layer including the base material containing, on its surface, an ion-exchange group is preferred. The surface-modified base material is not particularly limited, and in terms of easier production, a filter obtained by introducing an ion-exchange group into any of the foregoing polymers is preferred.

Examples of the ion-exchange group include cation-exchange groups such as a sulfonate group, a carboxy group, and a phosphate group and anion-exchange groups such as a quaternary ammonium group. Examples of methods of introducing an ion-exchange group into the polymer include, but are not limited to, reacting a compound containing an ion-exchange group and a polymerizable group with a polymer to cause, typically, grafting.

The ion-exchange group may be introduced by any method. For example, a fiber of any of the foregoing resins is irradiated with ionizing radiation (e.g., α-rays, β-rays, γ-rays, X-rays, or electron beams) to produce active moieties (radicals) in the resin. The resin that has been subjected to the irradiation is immersed in a monomer-containing solution to graft-polymerize the monomer onto the base material. As a result of this, a polymer in which the monomer is bonded to the polyolefin fiber as a graft-polymerized side chain is produced. The resin containing the produced polymer as a side chain is allowed to undergo a catalytic reaction with a compound containing an anion-exchange group or a cation-exchange group to introduce the ion-exchange group into the graft-polymerized side-chain polymer, thus providing a final product.

The filter may be in the form of a combination of a woven or nonwoven fabric on which an ion-exchange group is formed by radiation-induced graft polymerization and a conventional filtering material made of glass wool or a woven or nonwoven fabric.

When a filter containing an ion-exchange group is used, the content of particles containing a metal atom in the present treatment liquid is more easily controlled within a desired range. The material of the filter containing an ion-exchange group is not particularly limited, but is, for example, a material obtained by introducing the ion-exchange group into a polyfluorocarbon or a polyolefin, more preferably a material obtained by introducing the ion-exchange group into a polyfluorocarbon.

The pore size of the filter containing an ion-exchange group is not particularly limited, but is preferably 1 to 200 nm, more preferably 1 to 30 nm, still more preferably 3 to 20 nm. The filter containing an ion-exchange group may also serve as the filter having a smallest pore size already described or may be used separately from the filter having a smallest pore size. In particular, to provide the present treatment liquid that produces the advantageous effects of the present invention in a better manner, the filter containing an ion-exchange group and the filter not having an ion-exchange group and having a smallest pore size are preferably used in the filtration step.

The material of the filter having a smallest pore size already described is not particularly limited, but from the viewpoint of, for example, solvent resistance, in general, the material is preferably at least one selected from the group consisting of polyfluorocarbons and polyolefins, more preferably a polyolefin.

Thus, as the filter used in the filtration step, two or more filters made of different materials may be used, and, for example, two or more selected from the group consisting of filters made of polyolefins, polyfluorocarbons, polyamides, and materials obtained by introducing an ion-exchange group into these materials may be used.

### Pore Structure of Filter

The pore structure of the filter is not particularly limited and may be appropriately selected depending on the components in the purification target substance. In the present specification, the pore structure of the filter means pore size distribution, positional distribution of pores in the filter, pore shape, etc. and can be controlled typically by how the filter is produced.

For example, formation by sintering of powder of a resin or the like provides a porous membrane, and formation by a method such as electrospinning, electroblowing, or melt blowing provides a fibrous membrane. These membranes have different pore structures.

The term “porous membrane” refers to a membrane that retains components such as gels, particles, colloids, cells, and polyoligomers in the purification target substance but allows components that are substantially smaller than pores to pass through the pores. The retention of the components in the purification target substance by the porous membrane may depend on operating conditions such as face velocity, use of a surfactant, pH, and combinations thereof, and can depend on the pore size and structure of the porous membrane and the size and structure (e.g., hard or gelatinous) of particles to be removed.

When the purification target substance contains negatively charged particles, a polyamide filter functions as a non-sieving membrane to remove such particles. Typical non-sieving membranes include nylon membranes such as nylon-6 membranes and nylon-6,6 membranes, but are not limited thereto.

As used herein, the term “non-sieving” retention mechanism refers to retention caused by mechanisms such as blocking, diffusion, and adsorption not associated with the pressure drop or pore size of the filter.

Non-sieving retention includes retention mechanisms such as blocking, diffusion, and adsorption by which particles to be removed in the purification target substance are removed independent of the pressure drop of the filter or the pore size of the filter. The adsorption of particles to the filter surface can be mediated by, for example, the intermolecular van der Waals force and electrostatic force. The blocking effect occurs when particles moving through a non-sieving membrane layer having a meandering path cannot turn sufficiently fast so as to avoid contact with the non-sieving membrane. Particle transport by diffusion results mainly from the random or Brownian motion of small particles, which creates a certain probability of the particles colliding with the filtering material. When there is no repulsive force between the particles and the filter, the non-sieving retention mechanism can be active.

An ultra-high molecular weight polyethylene (UPE) filter is typically a sieving membrane. The sieving membrane means a membrane that captures particles mainly through the sieving retention mechanism or a membrane optimized in order to capture particles through the sieving retention mechanism.

Typical examples of the sieving membrane include polytetrafluoroethylene (PTFE) membranes and UPE membranes, but are not limited thereto.

The term “sieving retention mechanism” refers to retention resulting from the size of particles to be removed larger than the pore size of the porous membrane. The sieving retention force can be improved by formation of a filter cake (aggregation of particles to be removed on the surface of the membrane). The filter cake effectively functions as a secondary filter.

The material of the fibrous membrane is not particularly limited as long as it is a polymer that can form into the fibrous membrane. Examples of the polymer include polyamides. Examples of polyamides include nylon 6 and nylon 6,6. The polymer forming the fibrous membrane may be poly(ether sulfone). When the fibrous membrane is on the upstream side of the porous membrane, the surface energy of the fibrous membrane is preferably higher than that of a polymer forming the porous membrane on the downstream side. An example of such a combination is the case where the fibrous membrane is made of nylon and the porous membrane is made of polyethylene (UPE).

The method of producing the fibrous membrane is not particularly limited, and a known method can be used. Examples of the method of producing the fibrous membrane include electrospinning, electroblowing, and melt blowing.

The pore structure of the porous membrane (e.g., a porous membrane including UPE, PTFE, or the like) is not particularly limited, and the shape of pores may be, for example, a lace shape, a string shape, or a node shape.

The size distribution of pores in the porous membrane and their positional distribution in the membrane are not particularly limited. The size distribution may be narrower, and the positional distribution in the membrane may be symmetric. Alternatively, the size distribution may be wider, and the positional distribution in the membrane may be asymmetric (such a membrane is also referred to as an “asymmetric porous membrane”). In the case of an asymmetric porous membrane, the pore size varies in the membrane; typically, the pore size increases from one surface of the membrane toward the other surface of the membrane. Here, a surface on the side on which pores having larger sizes are predominant is also referred to as the “open side”, and a surface on the side on which pores having smaller sizes are predominant is also referred to as the “tight side”.

The asymmetric porous membrane may be, for example, a membrane in which the pore size minimizes at a certain position in the thickness direction of the membrane (this is also referred to as an “hourglass shape”).

Using the asymmetric porous membrane such that pores having larger sizes are present on the upstream side, that is, the upstream side is the open side, can produce a prefiltering effect.

The porous membrane may include a thermoplastic polymer such as polyethersulfone (PESU), a perfluoroalkoxyalkane (PFA, tetrafluoroethylene/perfluoroalkoxyalkane copolymer), a polyamide, or a polyolefin, or may include polytetrafluoroethylene or the like.

In particular, the material of the porous membrane is preferably ultra-high molecular weight polyethylene. The ultra-high molecular weight polyethylene, which means a thermoplastic polyethylene having an extremely long chain, has a molecular weight of 1,000,000 or more, typically preferably 2,000,000 to 6,000,000.

As the filter used in the filtration step, two or more filters having different pore structures may be used, or a porous membrane filter and a fibrous membrane filter may be used in combination. Specifically, for example, a nylon fibrous membrane filter and a UPE porous membrane filter may be used.

Preferably, the filter is sufficiently washed before use.

When an unwashed filter (or an insufficiently washed filter) is used, impurities contained in the filter tend to be incorporated into the present treatment liquid.

Examples of the impurities contained in the filter include the organic impurities described above, and if the filtration step is performed using an unwashed filter (or an insufficiently washed filter), the content of the organic impurities in the present treatment liquid may exceed the allowable range for the present treatment liquid.

For example, when a polyolefin such as UPE or a polyfluorocarbon such as PTFE is used for the filter, the filter tends to contain, as an impurity, an alkane having 12 to 50 carbon atoms.

When a polyamide such as nylon, a polyimide, or a polymer obtained by graft copolymerization of a polyolefin (e.g., UPE) with a polyamide (e.g., nylon) is used for the filter, the filter tends to contain, as an impurity, an alkene having 12 to 50 carbon atoms.

The method of washing the filter is, for example, immersion of the filter in an organic solvent having a low impurity content (e.g., an organic solvent purified by distillation (e.g., PGMEA)) for one week or more. In this case, the temperature of the organic solvent is preferably 30° C. to 90° C.

The degree of washing of the filter may be adjusted so that filtering the purification target substance using the filter provides a treatment liquid containing a desired amount of filter-derived organic impurities.

The filtration step may be a multistage filtration step in which the purification target substance is passed through two or more filters different in at least one selected from the group consisting of filter material, pore size, and pore structure.

The purification target substance may be passed through the same filter for multiple times, or the purification target substance may be passed through multiple filters of the same type.

The path of filtration is not particularly limited. Single-pass filtration may be employed, or cycle filtration may be performed with a circulation path assembled.

The material of a liquid-contact portion (which means an inner wall surface and other portions with which the purification target substance and the treatment liquid can come into contact) of a purification apparatus used in the filtration step is not particularly limited, but the liquid-contact portion is preferably formed of at least one selected from the group consisting of nonmetal materials (e.g., fluorocarbon resins) and electropolished metal materials (e.g., stainless steel) (hereinafter, these are also referred to collectively as “corrosion-resistant materials”). For example, when the liquid-contact portion of a production tank is formed of a corrosion-resistant material, the production tank itself may be formed of the corrosion-resistant material, or the inner wall surface and other portions of the production tank may be coated with the corrosion-resistant material.

The nonmetal material is not particularly limited, and a known material can be used.

Examples of the nonmetal material include at least one selected from the group consisting of polyethylene resin, polypropylene resin, polyethylene-polypropylene resin, and fluorocarbon resins (e.g., tetrafluoroethylene resin, tetrafluoroethylene-perfluoroalkyl vinyl ether copolymer, tetrafluoroethylene-hexafluoropropylene copolymer resin, tetrafluoroethylene-ethylene copolymer resin, trifluorochloroethylene-ethylene copolymer resin, vinylidene fluoride resin, trifluorochloroethylene copolymer resin, and vinyl fluoride resin), but are not limited thereto.

The metal material is not particularly limited, and a known material can be used.

The metal material is, for example, a metal material in which the total content of chromium and nickel is more than 25 mass % relative to the total mass of the metal material. In particular, the total content of chromium and nickel is more preferably 30 mass % or more. The upper limit of the total content of chromium and nickel in the metal material is not particularly limited, but in general, the upper limit is preferably 90 mass % or less.

The metal material is, for example, stainless steel or a nickel-chromium alloy.

The stainless steel is not particularly limited, and a known stainless steel can be used. In particular, an alloy containing 8 mass % or more of nickel is preferred, and an austenitic stainless steel containing 8 mass % or more of nickel is more preferred. Examples of the austenitic stainless steel include steel use stainless (SUS) 304 (Ni content, 8 mass %; Cr content, 18 mass %), SUS304L (Ni content, 9 mass %; Cr content, 18 mass %), SUS316 (Ni content, 10 mass %; Cr content, 16 mass %), and SUS316L (Ni content, 12 mass %; Cr content, 16 mass %).

The nickel-chromium alloy is not particularly limited, and a known nickel-chromium alloy can be used. In particular, a nickel-chromium alloy having a nickel content of 40 to 75 mass % and a chromium content of 1 to 30 mass % is preferred.

Examples of the nickel-chromium alloy include Hastelloy (product name, hereinafter the same), Monel (product name, hereinafter the same), and Inconel (product name, hereinafter the same). More specific examples include Hastelloy C-276 (Ni content, 63 mass %; Cr content, 16 mass %), Hastelloy-C(Ni content, 60 mass %; Cr content, 17 mass %), and Hastelloy C-22 (Ni content, 61 mass %; Cr content, 22 mass %).

If necessary, the nickel-chromium alloy may further contain, in addition to the above alloys, boron, silicon, tungsten, molybdenum, copper, cobalt, and the like.

The method of electropolishing the metal material is not particularly limited, and a known method can be used. For example, methods described in, for example, paragraphs [0011] to [0014] of JP2015-227501A and paragraphs [0036] to [0042] of JP2008-264929A can be used.

It is presumed that in the metal material, the chromium content in a surface passivation layer has been increased by electropolishing to be higher than the chromium content in the matrix. Thus, it is presumed that when a purification apparatus whose liquid-contact portion is formed of an electropolished metal material is used, metal-containing particles are less likely to flow out into the purification target substance.

The metal material may be buffed. The method of buffing is not particularly limited, and a known method can be used. The size of polishing abrasive grains used for the finish of buffing is not particularly limited, but is preferably #400 or less to readily reduce surface irregularities of the metal material. The buffing is preferably performed before the electropolishing.

### Other Steps

The method for producing the present treatment liquid may further have steps other than the filtration step. Examples of the steps other than the filtration step include a distillation step, a reaction step, and a neutralization step.

### Distillation Step

The distillation step is a step of distilling the purification target substance containing an organic solvent to obtain a distilled purification target substance. The method of distilling the purification target substance is not particularly limited, and a known method can be used. In a typical method, for example, a distillation column is disposed on the upstream side of the purification apparatus used in the filtration step, and the distilled purification target substance is introduced into the production tank.

Here, the liquid-contact portion of the distillation column is preferably, but not necessarily, formed of a corrosion-resistant material as already described.

### Reaction Step

The reaction step is a step of reacting raw materials together to produce a reaction product, that is, the purification target substance containing an organic solvent. The method of producing the purification target substance is not particularly limited, and a known method can be used. In a typical method, for example, a reactor is disposed on the upstream side of the production tank (or the distillation column) of the purification apparatus used in the filtration step, and the reaction product is introduced into the production tank (or the distillation column).

Here, the liquid-contact portion of the production tank is preferably, but not necessarily, formed of a corrosion-resistant material as already described.

### Neutralization Step

The neutralization step is a step of neutralizing the purification target substance to reduce the charge potential of the purification target substance.

The method of neutralization is not particularly limited, and a known neutralization method can be used. An example of the neutralization method is to bring the purification target substance into contact with a conductive material.

The contact time for which the purification target substance is brought into contact with the conductive material is preferably 0.001 to 60 seconds, more preferably 0.001 to 1 second, particularly preferably 0.01 to 0.1 seconds. Examples of the conductive material include stainless steel, gold, platinum, diamond, and glassy carbon.

An example of the method of bringing the purification target substance into contact with the conductive material is to pass the purification target substance through a grounded mesh made of the conductive material, the grounded mesh being disposed inside the conduit.

The purification of the purification target substance, involving opening of a container, washing of the container and apparatus, loading of a solution, analysis, etc., is preferably all performed in a clean room. The clean room is preferably a clean room at a cleanliness level of class 4 or higher defined in International Standard ISO 14644-1: 2015 established by International Organization for Standardization. Specifically, the clean room preferably satisfies any one of ISO class 1, ISO class 2, ISO class 3, and ISO class 4, more preferably satisfies ISO class 1 or ISO class 2, particularly preferably satisfies ISO class 1.

The present treatment liquid may be stored at any temperature, but is preferably stored at 4° C. or higher, at which temperatures impurities and the like contained in trace amounts in the present treatment liquid are less likely to leach out, and as a result the advantageous effects of the present invention are better produced.

In addition to the above steps, a dehydration step may be performed. The dehydration step can be performed using, for example, distillation or a molecular sieve.

### Treatment Liquid Housing Body

The present treatment liquid may be used immediately after being produced or may be stored until use while being housed in a container. The combination of such a container and the present treatment liquid housed in the container is referred to as a treatment liquid housing body. The present treatment liquid is taken out of the stored treatment liquid housing body and used.

For use in the production of semiconductor devices, the container for storing the present treatment liquid preferably has the following features: the cleanliness class in the container is high, and impurities are less likely to leach out.

Specific examples of usable containers include “CLEAN Bottle” series manufactured by Aicello Corporation and “Pure bottle” manufactured by Kodama Plastics Co., Ltd., but are not limited thereto.

For the purpose of preventing impurity contamination of the present treatment liquid, the container is also preferably a multi-layer bottle whose inner wall has a six-layer structure composed of six types of resins or a multi-layer bottle whose inner wall has a seven-layer structure composed of six types of resins. Examples of such containers include containers described in JP2015-123351A.

At least a part of a liquid-contact portion of the container may be made of metal (preferably stainless steel, more preferably electropolished stainless steel), fluorocarbon resin, or glass, and is preferably made of metal for the advantageous effects of the present invention to be better produced.

### EXAMPLES

The present invention will now be described in more detail with reference to Examples. The materials, amounts, proportions, treatments, treatment sequences, etc. given in the following Examples may be changed as appropriate without departing from the spirit of the present invention. Thus, the scope of the present invention should not be construed as being limited by the Examples given below.

### Production of Treatment Liquids of Examples and Comparative Examples

Components shown in Tables below were mixed together to obtain treatment liquids of Examples and Comparative Examples.

First, organic solvents (an aliphatic hydrocarbon solvent and an ester solvent) were purified through low-temperature distillation in an airtight container made of Teflon (registered trademark) and filter filtration. The purification was repeated until the specific metallic element content (measured by ICP-MS described later) fell below 1 mass ppt.

Next, the purified aliphatic hydrocarbon solvent and ester solvent were mixed such that the contents thereof were as shown in Table below, and components other than the organic solvents were then added such that the contents thereof were as shown in Table 1. In this manner, the treatment liquids of Examples and Comparative Examples were obtained.

Here, in the preparation of the treatment liquids, all the operations for preparing the components were performed in an ISO class 3 clean booth to prevent contamination. The containers and equipment for use in the preparation of the components and the measurement of, for example, the contents of the components were selected from those whose liquid-contact portions were made of Teflon (registered trademark), glass, or electropolished stainless steel. The liquid-contact portions were thoroughly washed in advance using FN-DP001 manufactured by FUJIFILM Electronic Materials Co., Ltd. before use.

As the filter used for the filter filtration, a 7 nm PTFE filter manufactured by Nihon Entegris G.K., a 10 nm PE (polyethylene) filter manufactured by Nihon Entegris G.K., and a 5 nm nylon filter manufactured by Nihon Pall Ltd. were used alone or in appropriate combination.

For the organic solvents used in Example 12, concentration pretreatment by low-temperature heating was performed before the measurement so that the content of the specific metal contained in the original solvents was detectable on the order of 0.01 mass ppt. The liquid-contact portion of the apparatus for the concentration pretreatment was made of Teflon (registered trademark) or glass, and thoroughly washed with the treatment liquid of Example 12 before being used for the concentration pretreatment.

### Aliphatic Hydrocarbon Solvent

Undecane: Wako Special Grade manufactured by FUJIFILM Wako Pure Chemical Corporation
Decane: Wako Special Grade manufactured by FUJIFILM Wako Pure Chemical Corporation
Dodecane: Wako Special Grade manufactured by FUJIFILM Wako Pure Chemical Corporation
Methyldecane: reagent manufactured by FUJIFILM Wako Pure Chemical Corporation
Nonane: Wako Special Grade manufactured by FUJIFILM Wako Pure Chemical Corporation

### Specific Acid Component

Acetic acid: Ultra Pure Chemical from KANTO CHEMICAL CO., INC.
Propionic acid: Wako Special Grade manufactured by FUJIFILM Wako Pure Chemical Corporation
Butyric acid: Wako Special Grade manufactured by FUJIFILM Wako Pure Chemical Corporation
Formic acid: Wako Special Grade manufactured by FUJIFILM Wako Pure Chemical Corporation
Isobutyric acid: Wako Special Grade manufactured by FUJIFILM Wako Pure Chemical Corporation

### Ester Solvent

Butyl acetate: Wako Special Grade manufactured by FUJIFILM Wako Pure Chemical Corporation
Isobutyl acetate: Wako Special Grade manufactured by FUJIFILM Wako Pure Chemical Corporation
tert-Butyl acetate: Wako Special Grade manufactured by FUJIFILM Wako Pure Chemical Corporation
Amyl acetate: Wako Special Grade manufactured by FUJIFILM Wako Pure Chemical Corporation
Isoamyl acetate: Wako Special Grade manufactured by FUJIFILM Wako Pure Chemical Corporation
Propyl propionate: Wako Special Grade manufactured by FUJIFILM Wako Pure Chemical Corporation
Isopropyl propionate: Wako Special Grade manufactured by FUJIFILM Wako Pure Chemical Corporation
Butyl propionate: Wako Special Grade manufactured by FUJIFILM Wako Pure Chemical Corporation
Isobutyl propionate: Wako Special Grade manufactured by FUJIFILM Wako Pure Chemical Corporation
Ethyl butyrate: Wako Special Grade manufactured by FUJIFILM Wako Pure Chemical Corporation
Ethyl isobutyrate: Wako Special Grade manufactured by FUJIFILM Wako Pure Chemical Corporation
Amyl formate: Wako Special Grade manufactured by FUJIFILM Wako Pure Chemical Corporation
Isoamyl formate: Wako Special Grade manufactured by FUJIFILM Wako Pure Chemical Corporation
Propyl butyrate: reagent manufactured by Tokyo Chemical Industry Co., Ltd.
Isopropyl butyrate: reagent manufactured by FUJIFILM Wako Pure Chemical Corporation
Propyl isobutyrate: reagent manufactured by Tokyo Chemical Industry Co., Ltd.

### Water

Ultrapure water: sampled from an ultrapure water system manufactured by Nomura Micro Science Co., Ltd.

### Sulfur-Containing Compound

Thiophene: Wako Special Grade manufactured by FUJIFILM Wako Pure Chemical Corporation

### Aromatic Hydrocarbon

1,2,3,5-Tetramethylbenzene: reagent manufactured by FUJIFILM Wako Pure Chemical Corporation

### Alcohol

1-Butanol: Wako Special Grade manufactured by FUJIFILM Wako Pure Chemical Corporation Specific Metallic Element
Fe: ICPMS standard solution manufactured by FUJIFILM Wako Pure Chemical Corporation (Fe concentration: 100 mass ppm)
Ni: ICPMS standard solution manufactured by FUJIFILM Wako Pure Chemical Corporation (Ni concentration: 100 mass ppm)
Cr: ICPMS standard solution manufactured by FUJIFILM Wako Pure Chemical Corporation (Cr concentration: 100 mass ppm)

In each of Examples and Comparative Examples, a mixed solution obtained by mixing the ICPMS standard solution including Fe, the ICPMS standard solution including Ni, and the ICPMS standard solution including Cr in equal amounts was used. The mixed solution was serially diluted using the mother liquor of each of Examples and Comparative Examples and added such that the total content of Fe, Ni, and Cr elements was as shown in Table 1.

### Measurement of Contents of Components

The contents of a hydrocarbon solvent and an ester solvent in a treatment liquid were calculated from loading amounts.

For the contents of components other than the hydrocarbon solvent and the ester solvent, after the production of the treatment liquids, it was confirmed by the following measurement method that the contents of the components were as shown in Tables below.

### Contents of Specific Acid Component, Sulfur-Containing Component, Aromatic Hydrocarbon, and Alcohol

The contents of a specific acid component, a sulfur-containing component, an aromatic hydrocarbon, and an alcohol in a treatment liquid were measured using a gas chromatograph mass spectrometer (product name “GCMS-2020”, manufactured by Shimadzu Corporation).

### Measurement Conditions

Capillary column: InertCap 5MS/NP, 0.25 mm I.D.×30 m, df=0.25 μm
Sample introduction method: split, 75 kPa, constant pressure
Vaporization chamber temperature: 230° C.
Column oven temperature: 80° C. (2 min)-500° C. (13 min); heating rate, 15° C./min
Carrier gas: helium
Septum purge flow rate: 5 mL/min
Split ratio: 25:1
Interface temperature: 250° C.
Ion source temperature: 200° C.
Measurement mode: Scan m/z=85 to 500
Sample introduction volume: 1 μL

### Contents of Specific Metallic Elements

The contents of specific metallic elements (Fe, Ni, and Cr) in a treatment liquid (the total content of Fe, Ni, and Cr elements) were measured using Agilent 8900 Triple Quadrupole ICP-MS (for semiconductor analysis, option #200) under the following measurement conditions.

### Measurement Conditions

A sample introduction system including a quartz torch, a coaxial perfluoroalkoxyalkane (PFA) nebulizer (self-priming), and a platinum interface cone was used. The measurement parameters under cool plasma conditions are as follows.
Radio frequency (RF) output (W): 600
Carrier gas flow rate (L/min): 0.7
Make-up gas flow rate (L/min): 1
Sampling depth (mm): 18

For a treatment liquid in which the contents of the specific metallic elements were very small, the measurement was performed after low-temperature evaporation and concentration treatment were performed in advance using a synthetic quartz container, and the measured values were divided by the concentration ratio to determine the contents of the specific metallic elements.

### Content of Water

The content of water (water content) in a treatment liquid was measured using an apparatus (Karl Fischer moisture titrator MKA-610 manufactured by Kyoto Electronics Manufacturing Co., Ltd.) whose measurement principle was based on Karl Fischer water titration.

### Evaluation Tests

Using the treatment liquids of Examples and Comparative Examples, the following evaluations were performed.

### Defect

### Preparation of Resist Composition

The following components were mixed to prepare a mixed solution.
Polymer 1 54 parts by mass
Photoacid generator 31 parts by mass
Acid diffusion control agent 15 parts by mass
Propylene glycol monomethyl ether acetate 3430 parts by mass
Propylene glycol monomethyl ether 1470 parts by mass

Polymer 1 was a polymer having the following two repeating units and had a weight-average molecular weight of 8700 and a dispersity (Mw/Mn) of 1.23.

The molar ratio between the repeating unit represented by U-01 and the repeating unit represented by U-19 was 1:1.

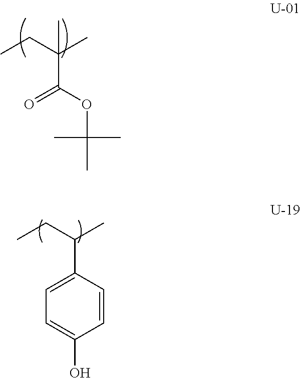

Photoacid generator (see the following structural formula)

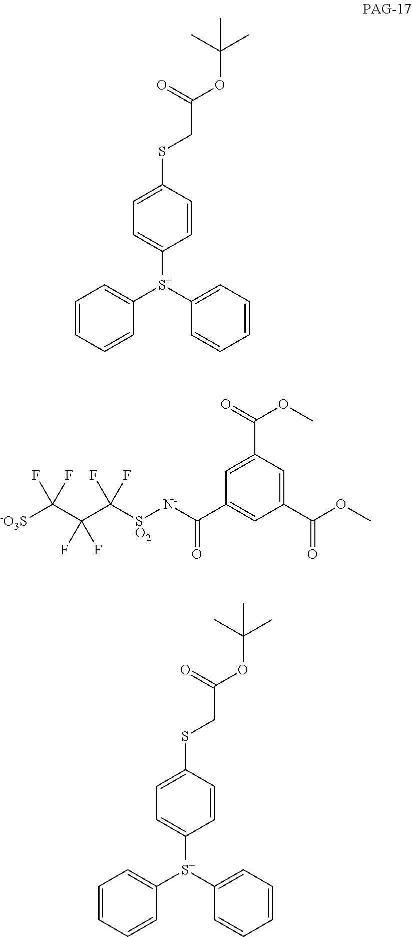

Acid diffusion control agent (see the following structural formula)

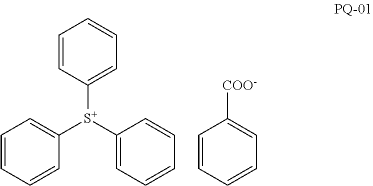

The mixed solution obtained above was then filtered through a polyethylene filter having a pore size of 0.03 μm to prepare a resist composition R-1.

### Method of Evaluating Defect

First, a composition SHB-A940 for underlayer film formation (manufactured by Shin-Etsu Chemical Co., Ltd.) was applied onto a 12-inch silicon wafer and baked at 205° C. for 60 seconds to form an underlayer film having a thickness of 20 nm. The resist composition R-1 prepared above was applied thereto and baked (PB) at 90° C. for 60 seconds to form a resist film having a thickness of 35 nm. Thus, a resist-film-carrying silicon wafer was produced.

The resist-film-carrying silicon wafer obtained was subjected to pattern exposure using an EUV exposure device (Micro Exposure Tool manufactured by Exitech Ltd.; NA, 0.3; Quadrupole; outer sigma, 0.68; inner sigma, 0.36). As a reticle, a photomask having a line size of 22 nm and a line-to-space ratio of 1:1 was used. Thereafter, after baking (PEB) was performed at 100° C. for 60 seconds, development was performed by puddling for 30 seconds using each of the treatment liquids (developers) of Examples and Comparative Examples, and the wafer was rotated at a rotation speed of 4000 rpm for 30 seconds, thereby obtaining a line-and-space pattern with a pitch of 28 to 50 nm.

The pattern obtained was evaluated by the number of defects on the substrate detected using Uvision8+ (manufactured by AMAT). The evaluation criteria are as follows.

### Evaluation Criteria

A: 50 or less
B: more than 50 and 200 or less
C: more than 200 and 1,000 or less
D: more than 1,000 and 10,000 or less
E: more than 10,000

### Warm Aging Defect

The evaluation was carried out in the same manner as the above defect evaluation except that a treatment liquid that had been stored in a SUS304 electropolishing container at 70° C. for 6 months was used. The evaluation criteria are as follows.

### Evaluation Criteria

A: 50 or less
B: more than 50 and 200 or less
C: more than 200 and 1,000 or less
D: more than 1,000 and 10,000 or less
E: more than 10,000

### Metal-Containing Defect

Among the defects on the substrate detected in the above defect evaluation, the number of defects containing at least one of Fe, Ni, or Cr was counted using a review SEM apparatus G-6 manufactured by Applied Materials, Inc. The evaluation criteria are shown below.

### Evaluation Criteria

A: 1 or less
B: more than 1 and 5 or less
C: more than 5 and 10 or less
D: more than 10 and 20 or less
E: more than 20

### Metal-Containing Warm Aging Defect

Among the defects on the substrate detected in the above warm aging defect evaluation, the number of defects containing at least one of Fe, Ni, or Cr was counted using a review SEM apparatus G-6 manufactured by Applied Materials, Inc. The evaluation criteria are shown below.

### Evaluation Criteria

A: 1 or less
B: more than 1 and 5 or less
C: more than 5 and 10 or less
D: more than 10 and 20 or less
E: more than 20

### Development

### Formation of Resist Film and Pattern Formation (Development)

A composition SHB-A940 for underlayer film formation (manufactured by Shin-Etsu Chemical Co., Ltd.) was applied onto a 12-inch silicon wafer and baked at 205° C. for 60 seconds to form an underlayer film having a thickness of 20 nm. The resist composition R-1 described above was applied thereto and baked (PB) at 90° C. for 60 seconds to form a resist film having a thickness of 35 nm. Thus, a resist-film-carrying silicon wafer was produced.

The resist-film-carrying silicon wafer obtained was subjected to pattern exposure using an EUV exposure device (Micro Exposure Tool manufactured by Exitech Ltd.; NA, 0.3; Quadrupole; outer sigma, 0.68; inner sigma, 0.36). As a reticle, a photomask having a line size of 14 to 25 nm and a line-to-space ratio of 1:1 was used. Thereafter, after baking (PEB) was performed at 100° C. for 60 seconds, development was performed by puddling for 30 seconds using each of the treatment liquids (developers) of Examples and Comparative Examples, and the wafer was rotated at a rotation speed of 4000 rpm for 30 seconds, thereby obtaining a line-and-space pattern with a pitch of 28 to 50 nm.

### Evaluation Criteria

In Formation of Resist Film and Pattern Formation (Development) above, an exposure dose at which a pattern having a line size of 14 to 25 nm and a line-to-space ratio of 1:1 was reproduced was employed as an optimum exposure dose (unit: mJ/cm²) for each line size.

A limit resolving power (a minimum line width at which a line and a space are separately resolved, limit resolution) at the optimum exposure dose was employed as a resolution (unit: nm). The evaluation criteria are as follows. For practical purposes, the evaluation result is preferably “C” or higher.
A: less than 18.0 nm
B: 18.0 nm or more and less than 19.0 nm
C: 19.0 nm or more and less than 20.0 nm
D: 20.0 nm or more and less than 21.0 nm
E: 21.0 nm or more

### Rinsing

### Formation of Resist Film and Pattern Formation (Rinsing Liquid)

A silicon wafer carrying a resist film having a thickness of 35 nm was formed by the same procedure as the formation method in Formation of Resist Film and Pattern Formation (Development) above.

The resist-film-carrying silicon wafer obtained was subjected to pattern exposure using an EUV exposure device (Micro Exposure Tool manufactured by Exitech Ltd.; NA, 0.3; Quadrupole; outer sigma, 0.68; inner sigma, 0.36). As a reticle, a photomask having a line size of 14 to 25 nm and a line-to-space ratio of 1:1 was used. Thereafter, after baking (PEB) was performed at 100° C. for 60 seconds, development was performed by puddling for 30 seconds with a developer FN-DP001 manufactured by FUJIFILM Electronic Materials Co., Ltd. The wafer, while being rotated at a rotation speed of 1000 rpm, was rinsed by pouring each of the treatment liquids (rinsing liquids) of Examples and Comparative Examples over the wafer for 10 seconds, and the wafer was then rotated at a rotation speed of 3000 rpm for 30 seconds to thereby obtain a line-and-space pattern with a pitch of 28 to 50 nm.

### Evaluation Criteria

In Formation of Resist Film and Pattern Formation (Rinsing Liquid) above, an exposure dose at which a pattern having a line size of 14 to 25 nm and a line-to-space ratio of 1:1 was reproduced was employed as an optimum exposure dose (unit: mJ/cm²) for each line size.

A limit resolving power (a minimum line width at which a line and a space are separately resolved, limit resolution) at the optimum exposure dose was employed as a resolution (unit: nm). The evaluation criteria are as follows. For practical purposes, the evaluation result is preferably “C” or higher.
A: less than 18.0 nm
B: 18.0 nm or more and less than 19.0 nm
C: 19.0 nm or more and less than 20.0 nm
D: 20.0 nm or more and less than 21.0 nm
E: 21.0 nm or more

### Cleaning

Using a semiconductor manufacturing equipment Lithius manufactured by Tokyo Electron Ltd., a developer FN-DP001 manufactured by FUJIFILM Electronic Materials Co., Ltd. was applied to three silicon substrates having a diameter of 300 mm, and the number of foreign bodies of ≥0.17 μm size on each substrate before and after the application was counted using Surfscan SP-5 manufactured by KLA-Tencor and confirmed to be 50 or less/substrate. In the treatment liquid feeding line thus confirmed, 3.79 L of a butyl acetate special grade reagent manufactured by FUJIFILM Wako Pure Chemical Corporation was allowed to flow to contaminate a feeding pipe, 10 L of each of the treatment liquids of Examples and Comparative Examples was then further allowed to flow to clean the pipe, and 10 L of FN-DP001 was allowed to flow again. After this process, application to substrates and counting of the number of foreign bodies were performed, and the cleaning effect was evaluated by the number of increased foreign bodies.

### Evaluation Criteria

A: 50 or less
B: more than 50 and 200 or less
C: more than 200 and 400 or less
D: more than 400 and 1,000 or less
E: more than 1,000

The results of the above evaluation tests are shown in Tables below.

In Tables, expressions such as “5.0E−08”, “1.7E+01”, and “1.3E+00” are abbreviations of exponential expressions. Specifically, for example, “5.0E−08” means “5.0×10⁻⁸”, “1.7E+01” means “1.7×10¹”, and “1.3E+00” means “1.3”.

In Tables, “Hydrocarbon solvent used in combination” means a hydrocarbon solvent used in combination with “Hydrocarbon solvent”.

In Tables, when two types of components are given in the column of “Specific acid component”, it means that the two types of components were used in combination, and the content means the total content of the two components. Specifically, for example, “formic acid/acetic acid” means that formic acid and acetic acid were used in combination.

In Tables, when two types of components are given in the column of “Ester solvent”, it means that the two types of components were used in combination, and their content is given separately for each kind. Specifically, for example, the expression “isoamyl formate/butyl acetate” means that isoamyl formate and butyl acetate were used in combination, and the expression “30/59” means that 30 mass % of isoamyl formate and 59 mass % of butyl acetate were used.

TABLE 1

| | | | Specific acid | | | | |
|---|---|---|---|---|---|---|---|
| | Hydrocarbon | | component | | | | Water |
| | solvent | | | Content | Ester solvent | | Content |
| Table 1 | | Content | | (mass | | Content | (mass |
| (1) | Type | (mass %) | Type | ppm) | Type | (mass %) | ppm) |
| Example 1 | undecane | balance | acetic acid | 2000 | butyl acetate | 90 | 87 |
| Example 2 | undecane | balance | acetic acid | 2000 | butyl acetate | 90 | 87 |
| Example 3 | undecane | balance | acetic acid | 4 | butyl acetate | 10 | 40 |
| Example 4 | undecane | balance | acetic acid | 3 | butyl acetate | 10 | 40 |
| Example 5 | undecane | balance | acetic acid | 5 | butyl acetate | 90 | 87 |
| Example 6 | undecane | balance | acetic acid | 30 | butyl acetate | 90 | 87 |
| Example 7 | undecane | balance | acetic acid | 50 | butyl acetate | 90 | 87 |
| Example 8 | undecane | balance | acetic acid | 150 | butyl acetate | 90 | 87 |
| Example 9 | undecane | balance | acetic acid | 700 | butyl acetate | 90 | 87 |
| Example 10 | undecane | balance | acetic acid | 1500 | butyl acetate | 90 | 87 |
| Example 11 | undecane | balance | acetic acid | 2000 | butyl acetate | 90 | 87 |
| Example 12 | undecane | balance | acetic acid | 5 | butyl acetate | 90 | 5 |
| Example 13 | undecane | balance | acetic acid | 1500 | butyl acetate | 90 | 470 |
| Example 14 | undecane | balance | acetic acid | 30 | butyl acetate | 90 | 5 |
| Example 15 | undecane | balance | acetic acid | 30 | butyl acetate | 90 | 790 |
| Example 16 | undecane | balance | acetic acid | 30 | butyl acetate | 90 | 1200 |
| Example 17 | undecane | balance | acetic acid | 30 | butyl acetate | 90 | 63 |
| Example 18 | undecane | balance | acetic acid | 30 | butyl acetate | 90 | 87 |
| Example 19 | undecane | balance | acetic acid | 30 | butyl acetate | 90 | 87 |
| Example 20 | undecane | balance | acetic acid | 30 | butyl acetate | 90 | 87 |
| Example 21 | undecane | balance | acetic acid | 30 | butyl acetate | 90 | 87 |
| Example 22 | undecane | balance | acetic acid | 30 | butyl acetate | 90 | 87 |

| | Sulfur- | | | Specific | Specific | Specific acid |
|---|---|---|---|---|---|---|
| | containing | Aromatic | | metallic | metallic | component/ |
| | compound | hydrocarbon | Alcohol | element | element/acid | aromatic |
| | Content | Content | Content | Content | component | hydrocarbon |
| Table 1 | (mass | (mass | (mass | (mass | (mass | (mass |
| (1) | ppm) | ppm) | ppm) | ppt) | ratio) | ratio) |
| Example 1 | 0.05 | 120 | 40 | 100 | 5.0E−08 | 1.7E+01 |
| Example 2 | 0.05 | 120 | 40 | 5 | 2.5E−09 | 1.7E+01 |
| Example 3 | 0.6 | 1200 | 2 | 100 | 2.5E−05 | 3.3E−03 |
| Example 4 | 0.6 | 1200 | 2 | 3 | 1.0E−06 | 2.5E−03 |
| Example 5 | 0.05 | 120 | 40 | 7 | 1.4E−06 | 4.2E−02 |
| Example 6 | 0.05 | 120 | 40 | 11 | 3.7E−07 | 2.5E−01 |
| Example 7 | 0.05 | 120 | 40 | 22 | 4.4E−07 | 4.2E−01 |
| Example 8 | 0.05 | 120 | 40 | 27 | 1.8E−07 | 1.3E+00 |
| Example 9 | 0.05 | 120 | 40 | 39 | 5.6E−08 | 5.8E+00 |
| Example 10 | 0.05 | 120 | 40 | 58 | 3.9E−08 | 1.3E+01 |
| Example 11 | 0.05 | 20 | 40 | 5 | 2.5E−09 | 1.0E+02 |
| Example 12 | 0.03 | 20 | 10 | 0.03 | 6.0E−09 | 2.5E−01 |
| Example 13 | 0.05 | 1500 | 1800 | 70 | 4.7E−08 | 1.0E+00 |
| Example 14 | 0.05 | 120 | 40 | 7 | 2.3E−07 | 2.5E−01 |
| Example 15 | 0.05 | 120 | 40 | 7 | 2.3E−07 | 2.5E−01 |
| Example 16 | 0.05 | 120 | 40 | 7 | 2.3E−07 | 2.5E−01 |
| Example 17 | 0.01 | 60 | 40 | 5 | 1.7E−07 | 5.0E−01 |
| Example 18 | 9 | 120 | 40 | 7 | 2.3E−07 | 2.5E−01 |
| Example 19 | 23 | 120 | 40 | 7 | 2.3E−07 | 2.5E−01 |
| Example 20 | 2 | 3500 | 40 | 22 | 7.3E−07 | 8.6E−03 |
| Example 21 | 0.05 | 120 | 7000 | 7 | 2.3E−07 | 2.5E−01 |
| Example 22 | 0.05 | 120 | 40 | 120 | 4.0E−06 | 2.5E−01 |

TABLE 2

| | Hydrocarbon solvent | | Specific acid component | | Ester solvent | | Water |
|---|---|---|---|---|---|---|---|
| Table 1 | | Content | | Content | | Content | Content |
| (2) | Type | (mass %) | Type | (mass ppm) | Type | (mass %) | (mass ppm) |
| Example 23 | undecane | balance | acetic acid | 40 | isobutyl acetate | 80 | 100 |
| Example 24 | undecane | balance | acetic acid | 40 | tert-butyl acetate | 80 | 100 |
| Example 25 | undecane | balance | acetic acid | 40 | amyl acetate | 80 | 100 |
| Example 26 | undecane | balance | acetic acid | 40 | isoamyl acetate | 80 | 100 |
| Example 27 | undecane | balance | propionic acid | 40 | propyl propionate | 80 | 100 |
| Example 28 | undecane | balance | propionic acid | 40 | isopropyl propionate | 80 | 100 |
| Example 29 | undecane | balance | butyric acid | 40 | butyl propionate | 80 | 100 |
| Example 30 | undecane | balance | butyric acid | 40 | isobutyl propionate | 80 | 100 |
| Example 31 | undecane | balance | formic acid | 40 | ethyl butyrate | 80 | 100 |
| Example 32 | undecane | balance | formic acid | 40 | ethyl isobutyrate | 80 | 100 |
| Example 33 | undecane | balance | formic acid | 60 | amyl formate | 80 | 100 |
| Example 34 | undecane | balance | formic acid | 60 | isoamyl formate | 80 | 100 |
| Example 35 | nonane | balance | formic acid | 60 | isoamyl formate | 80 | 100 |
| Example 36 | decane | balance | formic acid | 60 | isoamyl formate | 80 | 100 |
| Example 37 | dodecane | balance | formic acid | 60 | isoamyl formate | 80 | 100 |
| Example 38 | methyldecane | balance | formic acid | 60 | isoamyl formate | 80 | 100 |
| Example 39 | undecane | balance | formic acid | 100 | — | — | 100 |
| Example 40 | undecane | balance | acetic acid | 50 | butyl acetate | 99 | 100 |
| Example 41 | undecane | balance | acetic acid | 50 | butyl acetate | 99 | 100 |
| Example 42 | undecane | balance | acetic acid | 50 | butyl acetate | 98 | 100 |
| Example 43 | undecane | balance | acetic acid | 50 | butyl acetate | 95 | 100 |
| Example 44 | undecane | balance | acetic acid | 40 | butyl acetate | 80 | 100 |
| Example 45 | undecane | balance | acetic acid | 35 | butyl acetate | 70 | 100 |
| Example 46 | undecane | balance | acetic acid | 28 | butyl acetate | 50 | 100 |
| Example 47 | undecane | balance | acetic acid | 18 | butyl acetate | 30 | 100 |
| Comparative | undecane | balance | acetic acid | 0.5 | butyl acetate | 1 | 27 |
| Example 1 | | | | | | | |
| Comparative | undecane | balance | — | — | — | — | 27 |
| Example 2 | | | | | | | |
| Comparative | undecane | balance | acetic acid | 5000 | butyl acetate | 90 | 87 |
| Example 3 | | | | | | | |

| | Sulfur- | | | Specific | Specific | Specific acid |
|---|---|---|---|---|---|---|
| | containing | Aromatic | | metallic | metallic | component/ |
| | compound | hydrocarbon | Alcohol | element | element/acid | aromatic |
| Table 1 | Content | Content | Content | Content | component | hydrocarbon |
| (2) | (mass ppm) | (mass ppm) | (mass ppm) | (mass ppt) | (mass ratio) | (mass ratio) |
| Example 23 | 0.05 | 100 | 40 | 8 | 2.0E−07 | 4.0E−01 |
| Example 24 | 0.05 | 100 | 40 | 7 | 1.8E−07 | 4.0E−01 |
| Example 25 | 0.05 | 100 | 40 | 7 | 1.8E−07 | 4.0E−01 |
| Example 26 | 0.05 | 100 | 40 | 4 | 1.0E−07 | 4.0E−01 |
| Example 27 | 0.05 | 100 | 40 | 17 | 4.3E−07 | 4.0E−01 |
| Example 28 | 0.05 | 100 | 40 | 14 | 3.5E−07 | 4.0E−01 |
| Example 29 | 0.05 | 100 | 40 | 14 | 3.5E−07 | 4.0E−01 |
| Example 30 | 0.05 | 100 | 40 | 3 | 7.5E−08 | 4.0E−01 |
| Example 31 | 0.05 | 100 | 40 | 24 | 6.0E−07 | 4.0E−01 |
| Example 32 | 0.05 | 100 | 40 | 25 | 6.3E−07 | 4.0E−01 |
| Example 33 | 0.05 | 100 | 60 | 15 | 2.5E−07 | 6.0E−01 |
| Example 34 | 0.05 | 100 | 60 | 10 | 1.7E−07 | 6.0E−01 |
| Example 35 | 0.05 | 100 | 60 | 10 | 1.7E−07 | 6.0E−01 |
| Example 36 | 0.05 | 100 | 60 | 10 | 1.7E−07 | 6.0E−01 |
| Example 37 | 0.05 | 100 | 200 | 10 | 1.7E−07 | 6.0E−01 |
| Example 38 | 0.05 | 100 | 400 | 10 | 1.7E−07 | 6.0E−01 |
| Example 39 | 0.6 | 1200 | 2 | 10 | 1.0E−07 | 8.3E−02 |
| Example 40 | 0.02 | 1 | 40 | 8 | 1.6E−07 | 5.0E+01 |
| Example 41 | 0.02 | 10 | 40 | 8 | 1.6E−07 | 5.0E+00 |
| Example 42 | 0.02 | 20 | 40 | 9 | 1.8E−07 | 2.5E+00 |
| Example 43 | 0.03 | 60 | 40 | 11 | 2.2E−07 | 8.3E−01 |
| Example 44 | 0.08 | 240 | 40 | 13 | 3.3E−07 | 1.7E−01 |
| Example 45 | 0.1 | 360 | 20 | 13 | 3.7E−07 | 9.7E−02 |
| Example 46 | 0.12 | 600 | 15 | 17 | 6.1E−07 | 4.7E−02 |
| Example 47 | 0.14 | 840 | 10 | 16 | 8.9E−07 | 2.1E−02 |
| Comparative | 0.6 | 1200 | 2 | 22 | 4.4E−05 | 4.2E−04 |
| Example 1 | | | | | | |
| Comparative | 0.6 | 1200 | — | 19 | — | — |
| Example 2 | | | | | | |
| Comparative | 0.05 | 120 | 40 | 3 | 6.0E−10 | 4.2E+01 |
| Example 3 | | | | | | |

TABLE 3

| | | Warm | Metal- | Metal-containing | | | |
|---|---|---|---|---|---|---|---|
| Table 1 | | aging | containing | warm aging | | | |
| (3) | Defect | defect | defect | defect | Development | Rinsing | Cleaning |
| Example 1 | B | B | B | B | B | B | B |
| Example 2 | B | B | A | C | B | B | B |
| Example 3 | B | B | B | B | B | A | A |
| Example 4 | B | B | A | A | B | A | A |
| Example 5 | A | A | A | A | A | A | A |
| Example 6 | A | A | A | A | A | A | A |
| Example 7 | A | A | A | A | A | A | A |
| Example 8 | A | A | A | B | A | A | A |
| Example 9 | A | B | A | B | B | B | B |
| Example 10 | B | B | B | B | B | B | B |
| Example 11 | C | B | B | C | B | B | B |
| Example 12 | A | A | A | C | C | B | B |
| Example 13 | C | C | C | C | C | C | C |
| Example 14 | A | A | A | A | A | A | A |
| Example 15 | B | B | A | B | B | B | A |
| Example 16 | B | C | A | B | B | B | A |
| Example 17 | A | B | A | A | A | A | A |
| Example 18 | A | B | A | B | A | A | A |
| Example 19 | B | B | A | B | A | A | A |
| Example 20 | B | B | A | A | B | A | A |
| Example 21 | B | C | A | B | B | B | A |
| Example 22 | B | B | C | C | A | A | C |

TABLE 4

| | | Warm | Metal- | Metal-containing | | | |
|---|---|---|---|---|---|---|---|
| Table 1 | | aging | containing | warm aging | | | |
| (4) | Defect | defect | defect | defect | Development | Rinsing | Cleaning |
| Example 23 | A | A | A | A | A | A | A |
| Example 24 | A | A | A | A | A | A | A |
| Example 25 | A | A | A | A | A | A | A |
| Example 26 | A | A | A | A | A | A | A |
| Example 27 | A | A | A | A | A | A | A |
| Example 28 | A | A | A | A | A | A | A |
| Example 29 | A | A | A | A | A | A | A |
| Example 30 | A | A | A | A | A | A | A |
| Example 31 | A | A | A | A | A | A | A |
| Example 32 | A | A | A | A | A | A | A |
| Example 33 | A | A | A | A | A | A | A |
| Example 34 | A | A | A | A | A | A | A |
| Example 35 | A | A | A | A | A | A | A |
| Example 36 | A | A | A | A | A | A | A |
| Example 37 | B | A | A | A | A | A | A |
| Example 38 | B | A | A | A | A | A | A |
| Example 39 | B | B | A | B | C | C | A |
| Example 40 | A | A | A | A | C | C | A |
| Example 41 | A | A | A | A | C | C | A |
| Example 42 | A | A | A | A | B | B | A |
| Example 43 | A | A | A | A | A | A | A |
| Example 44 | A | A | A | A | A | A | A |
| Example 45 | A | A | A | A | A | A | A |
| Example 46 | A | A | A | A | B | A | A |
| Example 47 | A | A | A | A | B | B | A |
| Comparative | D | D | A | A | D | C | D |
| Example 1 | | | | | | | |
| Comparative | E | E | A | A | E | D | E |
| Example 2 | | | | | | | |
| Comparative | E | E | A | E | C | C | C |
| Example 3 | | | | | | | |

TABLE 5

| | | | Hydrocarbon | | Specific acid | | | |
|---|---|---|---|---|---|---|---|---|
| | Hydrocarbon | | solvent used in | | component | | | |
| | solvent | | combination | | | Content | Ester solvent | |
| Table 1 | | Content | | Content | | (mass | | Content |
| (5) | Type | (mass %) | Type | (mass %) | Type | ppm) | Type | (mass %) |
| Example 48 | nonane | balance | — | — | formic acid | 30 | isoamyl formate | 83 |
| Example 49 | decane | balance | — | — | formic acid/ | 50 | isoamyl formate/ | 30/59 |
| | | | | | acetic acid | | butyl acetate | |
| Example 50 | dodecane | balance | — | — | formic acid | 30 | isoamyl formate | 81 |
| Example 51 | methyldecane | balance | — | — | formic acid | 50 | isoamyl formate | 87 |
| Example 52 | undecane | balance | — | — | formic acid | 30 | isoamyl formate | 94 |
| Example 53 | nonane | balance | — | — | acetic acid | 50 | butyl acetate | 92 |
| Example 54 | decane | balance | — | — | acetic acid | 30 | butyl acetate | 90 |
| Example 55 | dodecane | balance | — | — | acetic acid | 50 | butyl acetate | 76 |
| Example 56 | methyldecane | balance | — | — | acetic acid | 30 | butyl acetate | 98 |
| Example 57 | undecane | balance | — | — | acetic acid | 50 | butyl acetate | 86 |
| Example 58 | nonane | balance | — | — | acetic acid | 30 | isobutyl acetate | 84 |
| Example 59 | decane | balance | — | — | acetic acid | 50 | isobutyl acetate | 79 |
| Example 60 | dodecane | balance | — | — | acetic acid | 30 | isobutyl acetate | 95 |
| Example 61 | methyldecane | balance | — | — | acetic acid | 50 | isobutyl acetate/ | 40/42 |
| | | | | | | | butyl acetate | |
| Example 62 | undecane | balance | — | — | acetic acid | 30 | isobutyl acetate | 82 |
| Example 63 | nonane | balance | — | — | acetic acid | 30 | tert-butyl acetate | 85 |
| Example 64 | decane | balance | — | — | acetic acid | 30 | tert-butyl acetate | 70 |
| Example 65 | dodecane | balance | — | — | acetic acid | 30 | tert-butyl acetate | 92 |
| Example 66 | methyldecane | balance | — | — | acetic acid | 30 | tert-butyl acetate | 89 |
| Example 67 | undecane | balance | — | — | acetic acid | 30 | tert-butyl acetate | 79 |
| Example 68 | nonane | balance | — | — | propionic acid | 30 | propyl propionate | 91 |
| Example 69 | decane | balance | — | — | propionic acid | 30 | propyl propionate | 87 |
| Example 70 | dodecane | balance | — | — | propionic acid | 40 | propyl propionate | 80 |
| Example 71 | methyldecane | balance | — | — | propionic acid | 40 | propyl propionate | 92 |
| Example 72 | undecane | balance | — | — | propionic acid | 40 | propyl propionate | 90 |

| | | Sulfur- | | | Specific | Specific | Specific acid |
|---|---|---|---|---|---|---|---|
| | | containing | Aromatic | | metallic | metallic | component/ |
| | Water | compound | hydrocarbon | Alcohol | element | element/acid | aromatic |
| | Content | Content | Content | Content | Content | component | hydrocarbon |
| Table 1 | (mass | (mass | (mass | (mass | (mass | (mass | (mass |
| (5) | ppm) | ppm) | ppm) | ppm) | ppt) | ratio) | ratio) |
| Example 48 | 100 | 0.05 | 100 | 30 | 7 | 2.3E−07 | 3.0E−01 |
| Example 49 | 100 | 0.05 | 100 | 60 | 7 | 1.4E−07 | 5.0E−01 |
| Example 50 | 100 | 0.05 | 100 | 30 | 4 | 1.3E−07 | 3.0E−01 |
| Example 51 | 100 | 0.05 | 100 | 60 | 17 | 3.4E−07 | 5.0E−01 |
| Example 52 | 100 | 0.05 | 100 | 30 | 14 | 4.7E−07 | 3.0E−01 |
| Example 53 | 100 | 0.05 | 100 | 60 | 22 | 4.4E−07 | 5.0E−01 |
| Example 54 | 100 | 0.05 | 100 | 30 | 7 | 2.3E−07 | 3.0E−01 |
| Example 55 | 100 | 0.05 | 100 | 60 | 7 | 1.4E−07 | 5.0E−01 |
| Example 56 | 100 | 0.05 | 100 | 30 | 4 | 1.3E−07 | 3.0E−01 |
| Example 57 | 100 | 0.05 | 100 | 60 | 17 | 3.4E−07 | 5.0E−01 |
| Example 58 | 100 | 0.05 | 100 | 30 | 14 | 4.7E−07 | 3.0E−01 |
| Example 59 | 100 | 0.05 | 100 | 60 | 22 | 4.4E−07 | 5.0E−01 |
| Example 60 | 100 | 0.05 | 100 | 30 | 7 | 2.3E−07 | 3.0E−01 |
| Example 61 | 100 | 0.05 | 100 | 60 | 7 | 1.4E−07 | 5.0E−01 |
| Example 62 | 100 | 0.05 | 100 | 30 | 4 | 1.3E−07 | 3.0E−01 |
| Example 63 | 100 | 0.05 | 100 | 60 | 17 | 5.7E−07 | 3.0E−01 |
| Example 64 | 100 | 0.05 | 100 | 30 | 14 | 4.7E−07 | 3.0E−01 |
| Example 65 | 100 | 0.05 | 100 | 60 | 22 | 7.3E−07 | 3.0E−01 |
| Example 66 | 100 | 0.05 | 100 | 30 | 7 | 2.3E−07 | 3.0E−01 |
| Example 67 | 100 | 0.05 | 100 | 60 | 7 | 2.3E−07 | 3.0E−01 |
| Example 68 | 100 | 0.05 | 100 | 30 | 4 | 1.3E−07 | 3.0E−01 |
| Example 69 | 100 | 0.05 | 100 | 60 | 17 | 5.7E−07 | 3.0E−01 |
| Example 70 | 100 | 0.05 | 100 | 30 | 14 | 3.5E−07 | 4.0E−01 |
| Example 71 | 100 | 0.05 | 100 | 60 | 22 | 5.5E−07 | 4.0E−01 |
| Example 72 | 100 | 0.05 | 100 | 30 | 7 | 1.8E−07 | 4.0E−01 |

TABLE 6

| | | | | | Specific acid | | | |
|---|---|---|---|---|---|---|---|---|
| | Hydrocarbon | | Hydrocarbon solvent | | component | | | |
| | solvent | | used in combination | | | Content | Ester solvent | |
| Table 1 | | Content | | Content | | (mass | | Content |
| (6) | Type | (mass %) | Type | (mass %) | Type | ppm) | Type | (mass %) |
| Example 73 | nonane | balance | — | — | butyric acid | 40 | ethyl butyrate | 88 |
| Example 74 | decane | balance | — | — | butyric acid | 40 | ethyl butyrate | 77 |
| Example 75 | dodecane | balance | — | — | butyric acid | 40 | ethyl butyrate | 94 |
| Example 76 | methyldecane | balance | — | — | butyric acid | 40 | ethyl butyrate | 92 |
| Example 77 | undecane | balance | — | — | butyric acid | 40 | ethyl butyrate | 77 |
| Example 78 | nonane | balance | — | — | acetic acid | 40 | amyl acetate | 98 |
| Example 79 | decane | balance | — | — | acetic acid | 40 | amyl acetate | 92 |
| Example 80 | dodecane | balance | — | — | acetic acid | 60 | amyl acetate | 93 |
| Example 81 | methyldecane | balance | — | — | acetic acid | 60 | amyl acetate | 91 |
| Example 82 | undecane | balance | — | — | acetic acid | 60 | amyl acetate | 88 |
| Example 83 | nonane | balance | — | — | acetic acid | 60 | isoamyl acetate | 92 |
| Example 84 | decane | balance | — | — | acetic acid | 60 | isoamyl acetate | 86 |
| Example 85 | dodecane | balance | decane | 5 | acetic acid | 60 | isoamyl acetate | 90 |
| Example 86 | methyldecane | balance | — | — | acetic acid | 60 | isoamyl acetate | 87 |
| Example 87 | undecane | balance | — | — | acetic acid | 60 | isoamyl acetate | 93 |
| Example 88 | nonane | balance | — | — | propionic acid | 60 | butyl propionate | 92 |
| Example 89 | decane | balance | — | — | propionic acid | 60 | butyl propionate | 92 |
| Example 90 | dodecane | balance | — | — | propionic acid | 60 | butyl propionate | 94 |
| Example 91 | methyldecane | balance | — | — | propionic acid | 40 | butyl propionate | 85 |
| Example 92 | undecane | balance | — | — | propionic acid | 35 | butyl propionate | 93 |
| Example 93 | nonane | balance | undecane | 10 | propionic acid | 60 | isobutyl propionate | 86 |
| Example 94 | decane | balance | — | — | propionic acid | 60 | isobutyl propionate | 85 |
| Example 95 | dodecane | balance | — | — | propionic acid | 60 | isobutyl propionate | 87 |
| Example 96 | methyldecane | balance | — | — | propionic acid | 60 | isobutyl propionate | 90 |
| Example 97 | undecane | balance | — | — | propionic acid | 60 | isobutyl propionate | 88 |

| | | Sulfur- | | | Specific | Specific | Specific acid |
|---|---|---|---|---|---|---|---|
| | | containing | Aromatic | | metallic | metallic | component/ |
| | Water | compound | hydrocarbon | Alcohol | element | element/acid | aromatic |
| | Content | Content | Content | Content | Content | component | hydrocarbon |
| Table 1 | (mass | (mass | (mass | (mass | (mass | (mass | (mass |
| (6) | ppm) | ppm) | ppm) | ppm) | ppt) | ratio) | ratio) |
| Example 73 | 100 | 0.05 | 100 | 60 | 7 | 1.8E−07 | 4.0E−01 |
| Example 74 | 100 | 0.05 | 100 | 30 | 1 | 1.0E−07 | 4.0E−01 |
| Example 75 | 100 | 0.05 | 100 | 60 | 17 | 4.3E−07 | 4.0E−01 |
| Example 76 | 100 | 0.05 | 100 | 30 | 14 | 3.5E−07 | 4.0E−01 |
| Example 77 | 100 | 0.05 | 100 | 60 | 22 | 5.5E−07 | 4.0E−01 |
| Example 78 | 100 | 0.05 | 100 | 30 | 7 | 1.8E−07 | 4.0E−01 |
| Example 79 | 100 | 0.05 | 100 | 60 | 7 | 1.8E−07 | 4.0E−01 |
| Example 80 | 100 | 0.05 | 100 | 30 | 4 | 6.7E−08 | 6.0E−01 |
| Example 81 | 100 | 0.05 | 100 | 60 | 17 | 2.8E−07 | 6.0E−01 |
| Example 82 | 100 | 0.05 | 100 | 30 | 14 | 2.3E−07 | 6.0E−01 |
| Example 83 | 100 | 0.05 | 100 | 60 | 22 | 3.7E−07 | 6.0E−01 |
| Example 84 | 100 | 0.05 | 100 | 30 | 7 | 1.2E−07 | 6.0E−01 |
| Example 85 | 100 | 0.05 | 100 | 60 | 7 | 1.2E−07 | 6.0E−01 |
| Example 86 | 100 | 0.05 | 100 | 30 | 4 | 6.7E−08 | 6.0E−01 |
| Example 87 | 100 | 0.05 | 100 | 60 | 17 | 2.8E−07 | 6.0E−01 |
| Example 88 | 100 | 0.05 | 100 | 30 | 14 | 2.3E−07 | 6.0E−01 |
| Example 89 | 100 | 0.05 | 100 | 60 | 22 | 3.7E−07 | 6.0E−01 |
| Example 90 | 100 | 0.05 | 100 | 30 | 7 | 1.2E−07 | 6.0E−01 |
| Example 91 | 100 | 0.05 | 100 | 60 | 7 | 1.8E−07 | 4.0E−01 |
| Example 92 | 100 | 0.05 | 100 | 30 | 4 | 1.1E−07 | 3.5E−01 |
| Example 93 | 100 | 0.05 | 100 | 60 | 22 | 3.7E−07 | 6.0E−01 |
| Example 94 | 100 | 0.05 | 100 | 30 | 7 | 1.2E−07 | 6.0E−01 |
| Example 95 | 100 | 0.05 | 100 | 60 | 7 | 1.2E−07 | 6.0E−01 |
| Example 96 | 100 | 0.05 | 100 | 30 | 4 | 6.7E−08 | 6.0E−01 |
| Example 97 | 100 | 0.05 | 100 | 60 | 17 | 2.8E−07 | 6.0E−01 |

TABLE 7

| | | | Hydrocarbon | | Specific acid | | | |
|---|---|---|---|---|---|---|---|---|
| | Hydrocarbon | | solvent used in | | component | | | |
| | solvent | | combination | | | Content | Ester solvent | |
| Table 1 | | Content | | Content | | (mass | | Content |
| (7) | Type | (mass %) | Type | (mass %) | Type | ppm) | Type | (mass %) |
| Example 98 | nonane | balance | — | — | butyric acid | 60 | propyl butyrate | 85 |
| Example 99 | decane | balance | — | — | butyric acid | 60 | propyl butyrate | 86 |
| Example 100 | dodecane | balance | — | — | butyric acid | 60 | propyl butyrate | 95 |
| Example 101 | methyldecane | balance | — | — | butyric acid | 40 | propyl butyrate | 91 |
| Example 102 | undecane | balance | — | — | butyric acid | 35 | propyl butyrate | 87 |
| Example 103 | nonane | balance | — | — | butyric acid | 60 | isopropyl butyrate | 87 |
| Example 104 | decane | balance | — | — | butyric acid | 60 | isopropyl butyrate | 90 |
| Example 105 | dodecane | balance | — | — | butyric acid | 60 | isopropyl butyrate | 86 |
| Example 106 | methyldecane | balance | — | — | butyric acid | 60 | isopropyl butyrate | 85 |
| Example 107 | undecane | balance | — | — | butyric acid | 60 | isopropyl butyrate | 91 |
| Example 108 | nonane | balance | — | — | isobutyric acid | 60 | propyl isobutyrate | 87 |
| Example 109 | decane | balance | — | — | isobutyric acid | 60 | propyl isobutyrate | 95 |
| Example 110 | dodecane | balance | — | — | isobutyric acid | 60 | propyl isobutyrate | 94 |
| Example 111 | methyldecane | balance | — | — | isobutyric acid | 40 | propyl isobutyrate | 92 |
| Example 112 | undecane | balance | — | — | isobutyric acid | 35 | propyl isobutyrate | 85 |
| Example 113 | nonane | balance | — | — | formic acid/ | 60 | isoamyl formate/ | 10/81 |
| | | | | | acetic acid | | isoamyl acetate | |
| Example 114 | decane | balance | — | — | formic acid/ | 60 | isoamyl formate/ | 25/67 |
| | | | | | acetic acid | | isoamyl acetate | |
| Example 115 | dodecane | balance | — | — | formic acid/ | 60 | isoamyl formate/ | 40/42 |
| | | | | | acetic acid | | isoamyl acetate | |
| Example 116 | methyldecane | balance | — | — | formic acid/ | 40 | isoamyl formate/ | 55/39 |
| | | | | | acetic acid | | isoamyl acetate | |
| Example 117 | undecane | balance | — | — | formic acid/ | 35 | isoamyl formate/ | 70/24 |
| | | | | | acetic acid | | isoamyl acetate | |
| Example 118 | nonane | balance | — | — | formic acid/ | 60 | isoamyl formate/ | 10/70 |
| | | | | | propionic acid | | isobutyl propionate | |
| Example 119 | decane | balance | — | — | formic acid/ | 60 | isoamyl formate/ | 25/61 |
| | | | | | propionic acid | | isobutyl propionate | |
| Example 120 | dodecane | balance | — | — | formic acid/ | 60 | isoamyl formate/ | 40/46 |
| | | | | | propionic acid | | isobutyl propionate | |
| Example 121 | methyldecane | balance | — | — | formic acid/ | 60 | isoamyl formate/ | 55/35 |
| | | | | | propionic acid | | isobutyl propionate | |
| Example 122 | undecane | balance | — | — | formic acid/ | 60 | isoamyl formate/ | 70/22 |
| | | | | | propionic acid | | isobutyl propionate | |

| | | Sulfur- | | | Specific | Specific | Specific acid |
|---|---|---|---|---|---|---|---|
| | | containing | Aromatic | | metallic | metallic | component/ |
| | Water | compound | hydrocarbon | Alcohol | element | element/acid | aromatic |
| | Content | Content | Content | Content | Content | component | hydrocarbon |
| Table 1 | (mass | (mass | (mass | (mass | (mass | (mass | (mass |
| (7) | ppm) | ppm) | ppm) | ppm) | ppt) | ratio) | ratio) |
| Example 98 | 100 | 0.05 | 100 | 30 | 14 | 2.3E−07 | 6.0E−01 |
| Example 99 | 100 | 0.05 | 100 | 60 | 22 | 3.7E−07 | 6.0E−01 |
| Example 100 | 100 | 0.05 | 100 | 30 | 7 | 1.2E−07 | 6.0E−01 |
| Example 101 | 100 | 0.05 | 100 | 60 | 7 | 1.8E−07 | 4.0E−01 |
| Example 102 | 100 | 0.05 | 100 | 30 | 4 | 1.1E−07 | 3.5E−01 |
| Example 103 | 100 | 0.05 | 100 | 60 | 22 | 3.7E−07 | 6.0E−01 |
| Example 104 | 100 | 0.05 | 100 | 30 | 7 | 1.2E−07 | 6.0E−01 |
| Example 105 | 100 | 0.05 | 100 | 60 | 7 | 1.2E−07 | 6.0E−01 |
| Example 106 | 100 | 0.05 | 100 | 30 | 4 | 6.7E−08 | 6.0E−01 |
| Example 107 | 100 | 0.05 | 100 | 60 | 17 | 2.8E−07 | 6.0E−01 |
| Example 108 | 100 | 0.05 | 100 | 30 | 14 | 2.3E−07 | 6.0E−01 |
| Example 109 | 100 | 0.05 | 100 | 60 | 22 | 3.7E−07 | 6.0E−01 |
| Example 110 | 100 | 0.05 | 100 | 30 | 7 | 1.2E−07 | 6.0E−01 |
| Example 111 | 100 | 0.05 | 100 | 60 | 7 | 1.8E−07 | 4.0E−01 |
| Example 112 | 100 | 0.05 | 100 | 30 | 4 | 1.1E−07 | 3.5E−01 |
| Example 113 | 100 | 0.05 | 100 | 60 | 22 | 3.7E−07 | 6.0E−01 |
| Example 114 | 100 | 0.05 | 100 | 30 | 7 | 1.2E−07 | 6.0E−01 |
| Example 115 | 100 | 0.05 | 100 | 60 | 7 | 1.2E−07 | 6.0E−01 |
| Example 116 | 100 | 0.05 | 100 | 30 | 4 | 1.0E−07 | 4.0E−01 |
| Example 117 | 100 | 0.05 | 100 | 60 | 17 | 4.9E−07 | 3.5E−01 |
| Example 118 | 100 | 0.05 | 100 | 30 | 14 | 2.3E−07 | 6.0E−01 |
| Example 119 | 100 | 0.05 | 100 | 60 | 22 | 3.7E−07 | 6.0E−01 |
| Example 120 | 100 | 0.05 | 100 | 30 | 7 | 1.2E−07 | 6.0E−01 |
| Example 121 | 100 | 0.05 | 100 | 60 | 7 | 1.2E−07 | 6.0E−01 |
| Example 122 | 100 | 0.05 | 100 | 30 | 4 | 6.7E−08 | 6.0E−01 |

TABLE 8

| | | | Hydrocarbon | | Specific acid | | |
|---|---|---|---|---|---|---|---|
| | Hydrocarbon | | solvent used in | | component | | |
| | solvent | | combination | | | Content | |
| Table 1 | | Content | | Content | | (mass | Ester solvent |
| (8) | Type | (mass %) | Type | (mass %) | Type | ppm) | Type |
| Example 123 | nonane | balance | — | — | formic acid/butyric acid | 60 | isoamyl formate/propyl butyrate |
| Example 124 | decane | balance | — | — | formic acid/butyric acid | 60 | isoamyl formate/propyl butyrate |
| Example 125 | dodecane | balance | — | — | formic acid/butyric acid | 60 | isoamyl formate/propyl butyrate |
| Example 126 | methyldecane | balance | — | — | formic acid/butyric acid | 40 | isoamyl formate/propyl butyrate |
| Example 127 | undecane | balance | — | — | formic acid/butyric acid | 35 | isoamyl formate/propyl butyrate |
| Example 128 | nonane | balance | — | — | acetic acid | 60 | butyl acetate/isoamyl acetate |
| Example 129 | decane | balance | — | — | acetic acid | 60 | butyl acetate/isoamyl acetate |
| Example 130 | dodecane | balance | — | — | acetic acid | 60 | butyl acetate/isoamyl acetate |
| Example 131 | methyldecane | balance | — | — | acetic acid | 40 | butyl acetate/isoamyl acetate |
| Example 132 | undecane | balance | — | — | acetic acid | 35 | butyl acetate/isoamyl acetate |
| Example 133 | nonane | balance | — | — | acetic acid/propionic acid | 60 | butyl acetate/butyl propionate |
| Example 134 | decane | balance | — | — | acetic acid/propionic acid | 60 | butyl acetate/butyl propionate |
| Example 135 | dodecane | balance | — | — | acetic acid/propionic acid | 60 | butyl acetate/butyl propionate |
| Example 136 | methyldecane | balance | — | — | acetic acid/propionic acid | 60 | butyl acetate/butyl propionate |
| Example 137 | undecane | balance | — | — | acetic acid/propionic acid | 60 | butyl acetate/butyl propionate |
| Example 138 | nonane | balance | — | — | acetic acid/butyric acid | 60 | butyl acetate/propyl butyrate |
| Example 139 | decane | balance | — | — | acetic acid/butyric acid | 60 | butyl acetate/propyl butyrate |
| Example 140 | dodecane | balance | undecane | 10 | acetic acid/butyric acid | 60 | butyl acetate/propyl butyrate |
| Example 141 | methyldecane | balance | — | — | acetic acid/butyric acid | 40 | butyl acetate/propyl butyrate |
| Example 142 | undecane | balance | — | — | acetic acid/butyric acid | 35 | butyl acetate/propyl butyrate |
| Example 143 | nonane | balance | — | — | acetic acid | 60 | isobutyl acetate/isoamyl acetate |
| Example 144 | decane | balance | — | — | acetic acid | 60 | isobutyl acetate/isoamyl acetate |
| Example 145 | dodecane | balance | — | — | acetic acid | 60 | isobutyl acetate/isoamyl acetate |
| Example 146 | methyldecane | balance | — | — | acetic acid | 40 | isobutyl acetate/isoamyl acetate |
| Example 147 | undecane | balance | — | — | acetic acid | 35 | isobutyl acetate/isoamyl acetate |

| | | | Sulfur- | | | Specific | Specific | Specific acid |
|---|---|---|---|---|---|---|---|---|
| | | | containing | Aromatic | | metallic | metallic | component/ |
| | Ester | Water | compound | hydrocarbon | Alcohol | element | element/acid | aromatic |
| | solvent | Content | Content | Content | Content | Content | component | hydrocarbon |
| Table 1 | Content | (mass | (mass | (mass | (mass | (mass | (mass | (mass |
| (8) | (mass %) | ppm) | ppm) | ppm) | ppm) | ppt) | ratio) | ratio) |
| Example 123 | 10/83 | 100 | 0.05 | 100 | 60 | 22 | 3.7E−07 | 6.0E−01 |
| Example 124 | 25/58 | 100 | 0.05 | 100 | 30 | 7 | 1.2E−07 | 6.0E−01 |
| Example 125 | 40/45 | 100 | 0.05 | 100 | 60 | 7 | 1.2E−07 | 6.0E−01 |
| Example 126 | 55/26 | 100 | 0.05 | 100 | 30 | 4 | 1.0E−07 | 4.0E−01 |
| Example 127 | 70/16 | 100 | 0.05 | 100 | 60 | 17 | 4.9E−07 | 3.5E−01 |
| Example 128 | 10/77 | 100 | 0.05 | 100 | 60 | 22 | 3.7E−07 | 6.0E−01 |
| Example 129 | 25/58 | 100 | 0.05 | 100 | 30 | 7 | 1.2E−07 | 6.0E−01 |
| Example 130 | 40/47 | 100 | 0.05 | 100 | 60 | 7 | 1.2E−07 | 6.0E−01 |
| Example 131 | 55/36 | 100 | 0.05 | 100 | 30 | 4 | 1.0E−07 | 4.0E−01 |
| Example 132 | 70/18 | 100 | 0.05 | 100 | 60 | 17 | 4.9E−07 | 3.5E−01 |
| Example 133 | 10/82 | 100 | 0.05 | 100 | 30 | 14 | 2.3E−07 | 6.0E−01 |
| Example 134 | 25/65 | 100 | 0.05 | 100 | 60 | 22 | 3.7E−07 | 6.0E−01 |
| Example 135 | 40/55 | 100 | 0.05 | 100 | 30 | 7 | 1.2E−07 | 6.0E−01 |
| Example 136 | 55/25 | 100 | 0.05 | 100 | 60 | 7 | 1.2E−07 | 6.0E−01 |
| Example 137 | 70/11 | 100 | 0.05 | 100 | 30 | 4 | 6.7E−08 | 6.0E−01 |
| Example 138 | 10/70 | 100 | 0.05 | 100 | 60 | 22 | 3.7E−07 | 6.0E−01 |
| Example 139 | 25/65 | 100 | 0.05 | 100 | 30 | 7 | 1.2E−07 | 6.0E−01 |
| Example 140 | 40/41 | 100 | 0.05 | 100 | 60 | 7 | 1.2E−07 | 6.0E−01 |
| Example 141 | 55/40 | 100 | 0.05 | 100 | 30 | 4 | 1.0E−07 | 4.0E−01 |
| Example 142 | 70/19 | 100 | 0.05 | 100 | 60 | 17 | 4.9E−07 | 3.5E−01 |
| Example 143 | 10/73 | 100 | 0.05 | 100 | 60 | 22 | 3.7E−07 | 6.0E−01 |
| Example 144 | 25/69 | 100 | 0.05 | 100 | 30 | 7 | 1.2E−07 | 6.0E−01 |
| Example 145 | 40/45 | 100 | 0.05 | 100 | 60 | 7 | 1.2E−07 | 6.0E−01 |
| Example 146 | 55/29 | 100 | 0.05 | 100 | 30 | 4 | 1.0E−07 | 4.0E−01 |
| Example 147 | 70/14 | 100 | 0.05 | 100 | 60 | 17 | 4.9E−07 | 3.5E−01 |

TABLE 9

| | | | Hydrocarbon | | Specific acid | | | |
|---|---|---|---|---|---|---|---|---|
| | Hydrocarbon | | solvent used in | | component | | | |
| | solvent | | combination | | | Content | Ester solvent | |
| Table 1 | | Content | | Content | | (mass | | Content |
| (9) | Type | (mass %) | Type | (mass %) | Type | ppm) | Type | (mass %) |
| Example 148 | nonane | balance | — | — | acetic acid/ | 60 | isobutyl acetate/ | 10/76 |
| | | | | | propionic acid | | isobutyl propionate | |
| Example 149 | decane | balance | — | — | acetic acid/ | 60 | isobutyl acetate/ | 25/56 |
| | | | | | propionic acid | | isobutyl propionate | |
| Example 150 | dodecane | balance | — | — | acetic acid/ | 60 | isobutyl acetate/ | 40/40 |
| | | | | | propionic acid | | isobutyl propionate | |
| Example 151 | methyldecane | balance | — | — | acetic acid/ | 60 | isobutyl acetate/ | 55/32 |
| | | | | | propionic acid | | isobutyl propionate | |
| Example 152 | undecane | balance | — | — | acetic acid/ | 60 | isobutyl acetate/ | 70/24 |
| | | | | | propionic acid | | isobutyl propionate | |
| Example 153 | nonane | balance | — | — | acetic acid/ | 60 | isobutyl acetate/ | 10/73 |
| | | | | | butyric acid | | propyl butyrate | |
| Example 154 | decane | balance | — | — | acetic acid/ | 60 | isobutyl acetate/ | 25/55 |
| | | | | | butyric acid | | propyl butyrate | |
| Example 155 | dodecane | balance | — | — | acetic acid/ | 60 | isobutyl acetate/ | 40/49 |
| | | | | | butyric acid | | propyl butyrate | |
| Example 156 | methyldecane | balance | — | — | acetic acid/ | 40 | isobutyl acetate/ | 55/35 |
| | | | | | butyric acid | | propyl butyrate | |
| Example 157 | undecane | balance | — | — | acetic acid/ | 35 | isobutyl acetate/ | 70/14 |
| | | | | | butyric acid | | propyl butyrate | |

| | | Sulfur- | | | Specific | Specific | Specific acid |
|---|---|---|---|---|---|---|---|
| | | containing | Aromatic | | metallic | metallic | component/ |
| | Water | compound | hydrocarbon | Alcohol | element | element/acid | aromatic |
| | Content | Content | Content | Content | Content | component | hydrocarbon |
| Table 1 | (mass | (mass | (mass | (mass | (mass | (mass | (mass |
| (9) | ppm) | ppm) | ppm) | ppm) | ppt) | ratio) | ratio) |
| Example 148 | 100 | 0.05 | 100 | 30 | 14 | 2.3E−07 | 6.0E−01 |
| Example 149 | 100 | 0.05 | 100 | 60 | 22 | 3.7E−07 | 6.0E−01 |
| Example 150 | 100 | 0.05 | 100 | 30 | 7 | 1.2E−07 | 6.0E−01 |
| Example 151 | 100 | 0.05 | 100 | 60 | 7 | 1.2E−07 | 6.0E−01 |
| Example 152 | 100 | 0.05 | 100 | 30 | 4 | 6.7E−08 | 6.0E−01 |
| Example 153 | 100 | 0.05 | 100 | 60 | 22 | 3.7E−07 | 6.0E−01 |
| Example 154 | 100 | 0.05 | 100 | 30 | 7 | 1.2E−07 | 6.0E−01 |
| Example 155 | 100 | 0.05 | 100 | 60 | 7 | 1.2E−07 | 6.0E−01 |
| Example 156 | 100 | 0.05 | 100 | 30 | 4 | 1.0E−07 | 4.0E−01 |
| Example 157 | 100 | 0.05 | 100 | 60 | 17 | 4.9E−07 | 3.5E−01 |

TABLE 10

| | | Warm | Metal- | Metal-containing | | | |
|---|---|---|---|---|---|---|---|
| Table 1 | | aging | containing | warm aging | | | |
| (10) | Defect | defect | defect | defect | Development | Rinsing | Cleaning |
| Example 48 | A | A | A | A | A | A | A |
| Example 49 | A | A | A | A | A | A | A |
| Example 50 | A | A | A | A | A | A | A |
| Example 51 | A | A | A | A | A | A | A |
| Example 52 | A | A | A | A | A | A | A |
| Example 53 | A | A | A | A | A | A | A |
| Example 54 | A | A | A | A | A | A | A |
| Example 55 | A | A | A | A | A | A | A |
| Example 56 | A | A | A | A | A | A | A |
| Example 57 | A | A | A | A | A | A | A |
| Example 58 | A | A | A | A | A | A | A |
| Example 59 | A | A | A | A | A | A | A |
| Example 60 | A | A | A | A | A | A | A |
| Example 61 | A | A | A | A | A | A | A |
| Example 62 | A | A | A | A | A | A | A |
| Example 63 | A | A | A | A | A | A | A |
| Example 64 | A | A | A | A | A | A | A |
| Example 65 | A | A | A | A | A | A | A |
| Example 66 | A | A | A | A | A | A | A |
| Example 67 | A | A | A | A | A | A | A |
| Example 68 | A | A | A | A | A | A | A |
| Example 69 | A | A | A | A | A | A | A |
| Example 70 | A | A | A | A | A | A | A |
| Example 71 | A | A | A | A | A | A | A |
| Example 72 | A | A | A | A | A | A | A |

TABLE 11

| | | Warm | Metal- | Metal-containing | | | |
|---|---|---|---|---|---|---|---|
| Table 1 | | aging | containing | warm aging | | | |
| (11) | Defect | defect | defect | defect | Development | Rinsing | Cleaning |
| Example 73 | A | A | A | A | A | A | A |
| Example 74 | A | A | A | A | A | A | A |
| Example 75 | A | A | A | A | A | A | A |
| Example 76 | A | A | A | A | A | A | A |
| Example 77 | A | A | A | A | A | A | A |
| Example 78 | A | A | A | A | A | A | A |
| Example 79 | A | A | A | A | A | A | A |
| Example 80 | A | A | A | A | A | A | A |
| Example 81 | A | A | A | A | A | A | A |
| Example 82 | A | A | A | A | A | A | A |
| Example 83 | A | A | A | A | A | A | A |
| Example 84 | A | A | A | A | A | A | A |
| Example 85 | A | A | A | A | A | A | A |
| Example 86 | A | A | A | A | A | A | A |
| Example 87 | A | A | A | A | A | A | A |
| Example 88 | A | A | A | A | A | A | A |
| Example 89 | A | A | A | A | A | A | A |
| Example 90 | A | A | A | A | A | A | A |
| Example 91 | A | A | A | A | A | A | A |
| Example 92 | A | A | A | A | A | A | A |
| Example 93 | A | A | A | A | A | A | A |
| Example 94 | A | A | A | A | A | A | A |
| Example 95 | A | A | A | A | A | A | A |
| Example 96 | A | A | A | A | A | A | A |
| Example 97 | A | A | A | A | A | A | A |

TABLE 12

| | | Warm | Metal- | Metal-containing | | | |
|---|---|---|---|---|---|---|---|
| Table 1 | | aging | containing | warm aging | | | |
| (12) | Defect | defect | defect | defect | Development | Rinsing | Cleaning |
| Example 98 | A | A | A | A | A | A | A |
| Example 99 | A | A | A | A | A | A | A |
| Example 100 | A | A | A | A | A | A | A |
| Example 101 | A | A | A | A | A | A | A |
| Example 102 | A | A | A | A | A | A | A |
| Example 103 | A | A | A | A | A | A | A |
| Example 104 | A | A | A | A | A | A | A |
| Example 105 | A | A | A | A | A | A | A |
| Example 106 | A | A | A | A | A | A | A |
| Example 107 | A | A | A | A | A | A | A |
| Example 108 | A | A | A | A | A | A | A |
| Example 109 | A | A | A | A | A | A | A |
| Example 110 | A | A | A | A | A | A | A |
| Example 111 | A | A | A | A | A | A | A |
| Example 112 | A | A | A | A | A | A | A |
| Example 113 | A | A | A | A | A | A | A |
| Example 114 | A | A | A | A | A | A | A |
| Example 115 | A | A | A | A | A | A | A |
| Example 116 | A | A | A | A | A | A | A |
| Example 117 | A | A | A | A | A | A | A |
| Example 118 | A | A | A | A | A | A | A |
| Example 119 | A | A | A | A | A | A | A |
| Example 120 | A | A | A | A | A | A | A |
| Example 121 | A | A | A | A | A | A | A |
| Example 122 | A | A | A | A | A | A | A |

TABLE 13

| | | Warm | Metal- | Metal-containing | | | |
|---|---|---|---|---|---|---|---|
| Table 1 | | aging | containing | warm aging | | | |
| (13) | Defect | defect | defect | defect | Development | Rinsing | Cleaning |
| Example 123 | A | A | A | A | A | A | A |
| Example 124 | A | A | A | A | A | A | A |
| Example 125 | A | A | A | A | A | A | A |
| Example 126 | A | A | A | A | A | A | A |
| Example 127 | A | A | A | A | A | A | A |
| Example 128 | A | A | A | A | A | A | A |
| Example 129 | A | A | A | A | A | A | A |
| Example 130 | A | A | A | A | A | A | A |
| Example 131 | A | A | A | A | A | A | A |
| Example 132 | A | A | A | A | A | A | A |
| Example 133 | A | A | A | A | A | A | A |
| Example 134 | A | A | A | A | A | A | A |
| Example 135 | A | A | A | A | A | A | A |
| Example 136 | A | A | A | A | A | A | A |
| Example 137 | A | A | A | A | A | A | A |
| Example 138 | A | A | A | A | A | A | A |
| Example 139 | A | A | A | A | A | A | A |
| Example 140 | A | A | A | A | A | A | A |
| Example 141 | A | A | A | A | A | A | A |
| Example 142 | A | A | A | A | A | A | A |
| Example 143 | A | A | A | A | A | A | A |
| Example 144 | A | A | A | A | A | A | A |
| Example 145 | A | A | A | A | A | A | A |
| Example 146 | A | A | A | A | A | A | A |
| Example 147 | A | A | A | A | A | A | A |

TABLE 14

| | | Warm | Metal- | Metal-containing | | | |
|---|---|---|---|---|---|---|---|
| Table 1 | | aging | containing | warm aging | | | |
| (14) | Defect | defect | defect | defect | Development | Rinsing | Cleaning |
| Example 148 | A | A | A | A | A | A | A |
| Example 149 | A | A | A | A | A | A | A |
| Example 150 | A | A | A | A | A | A | A |
| Example 151 | A | A | A | A | A | A | A |
| Example 152 | A | A | A | A | A | A | A |
| Example 153 | A | A | A | A | A | A | A |
| Example 154 | A | A | A | A | A | A | A |
| Example 155 | A | A | A | A | A | A | A |
| Example 156 | A | A | A | A | A | A | A |
| Example 157 | A | A | A | A | A | A | A |

As shown in Table 1, it has been demonstrated that when the treatment liquids of Examples are used, the occurrence of defects is suppressed when the treatment liquids are applied onto a surface to be coated, and the occurrence of defects on a surface to be coated is suppressed when the treatment liquids are used after being housed in a container whose inner wall surface is made of metal (Examples).

Comparison of Examples 5 to 10 shows that when the content of a specific acid component is in the range of 5 to 50 mass ppm (Examples 5 to 7), each performance is higher.

Comparison of Example 6 and Example 11 shows that when the mass ratio of an acid component to an aromatic hydrocarbon is 1.0×10⁻³ to 50 (Example 6), each performance is higher.

Comparison of Examples 6 and 14 to 16 shows that when the content of water is 1 to 1000 mass ppm relative to the total mass of a treatment liquid (Examples 6, 14, and 15), the occurrence of defects can be further suppressed when the treatment liquid is used after being warmed.

Comparison of Examples 6 and 17 to 19 shows that when the content of a sulfur-containing compound is 0.01 to 10 mass ppm relative to the total mass of a treatment liquid (Examples 6, 17, and 18), the occurrence of defects can be further suppressed when the treatment liquid is used after being warmed while being housed in a container whose inner wall surface is made of metal.

Comparison of Example 40 and Example 20 shows that when the content of an aromatic hydrocarbon is 1 to 2000 mass ppm relative to the total mass of a treatment liquid (Example 40), each performance is higher.

Comparison of Example 6 and Example 21 shows that when the content of an alcohol is 1 to 5000 mass ppm relative to the total mass of a treatment liquid (Example 6), each performance is higher.

Comparison of Example 6 and Example 22 shows that when the content of a specific metallic element is 0.03 to 100 mass ppt relative to the total mass of a treatment liquid (Example 6), each performance is higher.

By contrast, it has been demonstrated that when the treatment liquids of Comparative Examples are used, the occurrence of defects is not sufficiently suppressed when the treatment liquids are applied onto a surface to be coated, or the occurrence of defects on a surface to be coated is not sufficiently suppressed when the treatment liquids are used after being housed in a container whose inner wall surface is made of metal (Comparative Examples).

### KrF Exposure

Using an underlayer film DUV44 (manufactured by Brewer Science, Inc.) and a resist composition R-2 below, a resist-film-carrying silicon wafer was produced. The resist-film-carrying silicon wafer was subjected to pattern irradiation using a KrF excimer laser scanner (PAS5500/850 manufactured by ASML) (NA, 0.80). Using, as a reticle, a 6% halftone mask having a line width of 100 nm and a line-to-space ratio of 1:1 in terms of on-wafer dimensions, a pattern with a line width of 100 nm was formed. Except for this, the treatment liquids (developers) of Examples and Comparative Examples were evaluated in the same manner as in Formation of Resist Film and Pattern Formation (Development) above.

The same results as in Formation of Resist Film and Pattern Formation (Development) above were obtained.

### Preparation of Resist Composition R-2

The following components were mixed to prepare a mixed solution.
Polymer 2 85 parts by mass
Photoacid generator 12 parts by mass
Acid diffusion control agent 3 parts by mass
Propylene glycol monomethyl ether acetate 3430 parts by mass
Propylene glycol monomethyl ether 1470 parts by mass

Polymer 2 was a polymer having the following three repeating units and had a weight-average molecular weight of 10000 and a dispersity (Mw/Mn) of 1.56. The molar ratio of the repeating units was 3:2:5 from left to right.

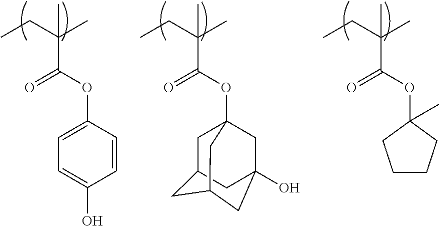

Photoacid generator (see the following structural formula)

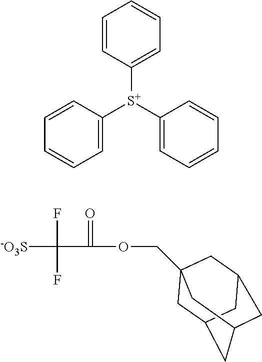

Acid diffusion control agent (see the following structural formula)

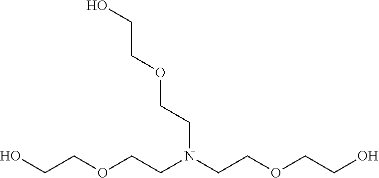 [SMILES: OCCOCCN(CCOCCO)CCOCCO]

The mixed solution obtained above was then filtered through a polyethylene filter having a pore size of 0.03 μm to prepare a resist composition R-2.

### ArF Exposure

Using an underlayer film ARC29SR (manufactured by Nissan Chemical Corporation) and a resist composition R-3 below, a resist-film-carrying silicon wafer was produced. The resist-film-carrying silicon wafer was subjected to pattern irradiation using an ArF excimer laser liquid immersion scanner (XT1700i manufactured by ASML; NA, 1.20; Dipole; outer sigma, 0.900; inner sigma, 0.700; Y deflection). Using, as a reticle, a 6% halftone mask having a line width of 50 nm and a line-to-space ratio of 1:1 in terms of on-wafer dimensions, a pattern with a line width of 50 nm was formed. Except for this, the treatment liquids (developers) of Examples and Comparative Examples were evaluated in the same manner as in Formation of Resist Film and Pattern Formation (Development) above.

The same results as in Formation of Resist Film and Pattern Formation (Development) above were obtained.

### Preparation of Resist Composition R-3

The following components were mixed to prepare a mixed solution.
Polymer 3 80 parts by mass
Photoacid generator 15 parts by mass
Acid diffusion control agent 5 parts by mass
Propylene glycol monomethyl ether acetate 3430 parts by mass
Propylene glycol monomethyl ether 1470 parts by mass

Polymer 3 was a polymer having the following three repeating units and had a weight-average molecular weight of 7800 and a dispersity (Mw/Mn) of 1.51. The molar ratio of the repeating units was 3:1:6 from left to right.

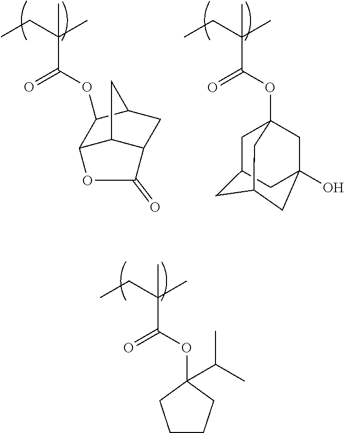

Photoacid generator (see the following structural formula)

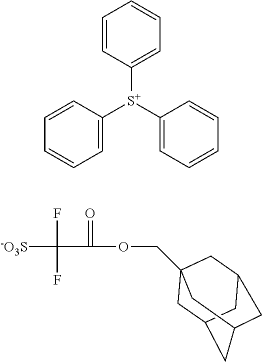

Acid diffusion control agent (see the following structural formula)

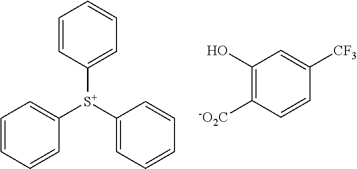

The mixed solution obtained above was then filtered through a polyethylene filter having a pore size of 0.03 μm to prepare a resist composition R-3.

### Electron Beam Exposure

Using an underlayer film DUV44 (manufactured by Brewer Science, Inc.) and a resist composition R-4 below, a resist-film-carrying silicon wafer was produced. The resist-film-carrying silicon wafer was subjected to pattern irradiation using an electron beam exposure device (EBM-9000 manufactured by NuFlare Technology Inc.; acceleration voltage, 50 kV). A pattern having a line width of 75 nm and a line-to-space ratio of 1:1 in terms of on-wafer dimensions was formed. Except for this, the treatment liquids (developers) of Examples and Comparative Examples were evaluated in the same manner as in Formation of Resist Film and Pattern Formation (Development) above.

The same results as in Formation of Resist Film and Pattern Formation (Development) above were obtained.

### Preparation of Resist Composition R-4

The following components were mixed to prepare a mixed solution.
Polymer 4 70 parts by mass
Photoacid generator 20 parts by mass
Acid diffusion control agent 10 parts by mass
Propylene glycol monomethyl ether acetate 3430 parts by mass
Propylene glycol monomethyl ether 1470 parts by mass

Polymer 4 was a polymer having the following four repeating units and had a weight-average molecular weight of 11000 and a dispersity (Mw/Mn) of 1.62. The molar ratio of the repeating units was 2:1:1:6 from left to right.

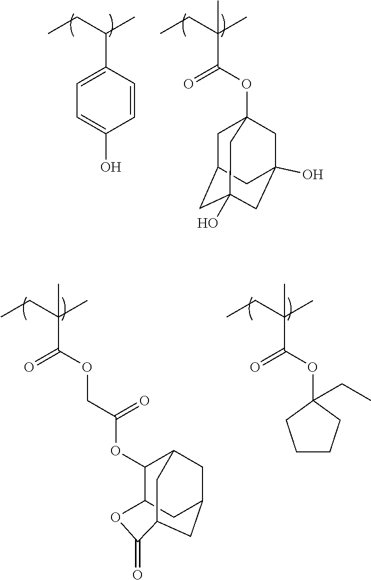

Photoacid generator (see the following structural formula)

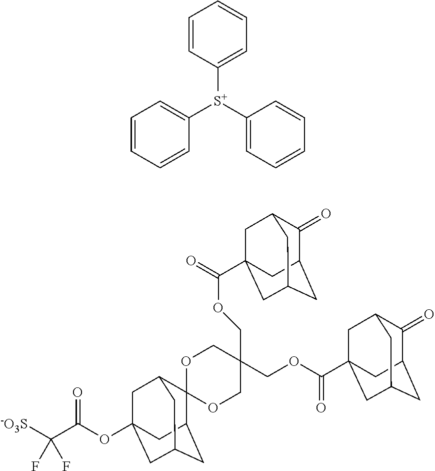

Acid diffusion control agent (see the following structural formula)

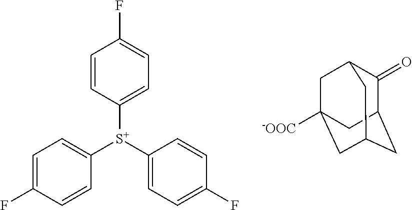

The mixed solution obtained above was then filtered through a polyethylene filter having a pore size of 0.03 μm to prepare a resist composition R-4.

What is claimed is:

1. A treatment liquid comprising:
an aliphatic hydrocarbon solvent;
an acid component that is at least one selected from the group consisting of carboxylic acids having a hydrocarbon group having 1 to 3 carbon atoms and formic acid; and
a metallic impurity including a metallic element that is at least one selected from the group consisting of Fe, Ni, and Cr,
wherein a mass ratio of a content of the metallic element to a content of the acid component is 1.0×10⁻⁹ to 3.0×10⁻⁵.

2. The treatment liquid according to claim 1, wherein the content of the metallic element is 0.03 to 100 mass ppt relative to a total mass of the treatment liquid.

3. The treatment liquid according to claim 1, wherein the content of the acid component is 1 to 2000 mass ppm relative to a total mass of the treatment liquid.

4. The treatment liquid according to claim 1, wherein the acid component includes acetic acid, and
a content of the acetic acid is 5 to 50 mass ppm relative to a total mass of the treatment liquid.

5. The treatment liquid according to claim 1, wherein a content of the aliphatic hydrocarbon solvent is 2 to 70 mass % relative to a total mass of the treatment liquid.

6. The treatment liquid according to claim 1, wherein the aliphatic hydrocarbon solvent includes at least one selected from the group consisting of nonane, decane, undecane, dodecane, and methyldecane.

7. The treatment liquid according to claim 1, further comprising an aromatic hydrocarbon.

8. The treatment liquid according to claim 7, wherein a mass ratio of the content of the acid component to a content of the aromatic hydrocarbon is 1.0×10⁻³ to 5.

9. The treatment liquid according to claim 7, wherein a content of the aromatic hydrocarbon is 1 to 2000 mass ppm relative to a total mass of the treatment liquid.

10. The treatment liquid according to claim 1, further comprising an ester solvent.

11. The treatment liquid according to claim 10, wherein a content of the ester solvent is 30 to 99 mass % relative to a total mass of the treatment liquid.

12. The treatment liquid according to claim 10, wherein the ester solvent includes butyl acetate.

13. The treatment liquid according to claim 1, further comprising water,
wherein a content of the water is 1 to 1000 mass ppm relative to a total mass of the treatment liquid.

14. The treatment liquid according to claim 1, further comprising a sulfur-containing compound,
wherein a content of the sulfur-containing compound is 0.01 to 10 mass ppm relative to a total mass of the treatment liquid.

15. The treatment liquid according to claim 1, further comprising an alcohol,
wherein a content of the alcohol is 1 to 5000 mass ppm relative to a total mass of the treatment liquid.

16. The treatment liquid according to claim 1, wherein the treatment liquid is used as a developer or a rinsing liquid.

17. The treatment liquid according to claim 1, wherein the treatment liquid is used as a developer for a negative-type resist film exposed with extreme ultraviolet rays.

18. A treatment liquid housing body comprising:
a container; and
the treatment liquid according to claim 1 housed in the container.

19. The treatment liquid housing body according to claim 18, wherein at least a part of a liquid-contact portion of the container is made of metal.

20. The treatment liquid according to claim 2, wherein the content of the acid component is 1 to 2000 mass ppm relative to a total mass of the treatment liquid.
